(19) United States
(12) Patent Application Publication
(10) Pub. No.: US 2026/0123535 A1
(43) Pub. Date: Apr. 30, 2026

(54) SPLICING MODULE, SPLICING DISPLAY SCREEN, AND MIDDLE FRAME

(71) Applicant: HUIZHOU JUFEI OPTOELECTRONICS LTD., Huizhou (CN)

(72) Inventors: Zhongjun XIAO, Huizhou (CN); Jun LI, Huizhou (CN); Meizheng XING, Huizhou (CN); Ni ZHANG, Huizhou (CN)

(73) Assignee: HUIZHOU JUFEI OPTOELECTRONICS LTD., Huizhou (CN)

(21) Appl. No.: 19/003,380

(22) Filed: Dec. 27, 2024

Related U.S. Application Data
(63) Continuation of application No. PCT/CN2023/103887, filed on Jun. 29, 2023.

(30) Foreign Application Priority Data
Jun. 29, 2022 (CN) 202210756999.7
Jun. 29, 2022 (CN) 202221667658.4
Dec. 16, 2022 (CN) 202211626564.7
Mar. 30, 2023 (CN) 202310334766.2

(51) Int. Cl. H01L 25/075; F21V 19/00; F21Y 115/10

(52) U.S. Cl. CPC H10W 90/00; F21V 19/005; F21Y 2115/10

(57) ABSTRACT

The present application relates to a splicing plate, a splicing plate component, a splicing display screen, a middle frame and a light board assembly, wherein the splicing plate is provided with a positioning pin that is integrally formed with the plate body and cooperates with the corresponding positioning pin hole on the middle frame, and wherein the plate body is provided with splicing through holes corresponding to the corresponding splicing screw holes on the middle frame.

### REFERENCE TO RELATED APPLICATIONS

The present application is a continuation of international application No. PCT/CN2023/103887, filed on Jun. 29, 2023, which claims the priority of CN application No. 202210756999.7, filed on Jun. 29, 2022, CN application No. 202221667658.4, filed on Jun. 29, 2022, CN application No. 202211626564.7, filed on Dec. 16, 2022, CN application No. 202310334766.2, filed on Mar. 30, 2023, the entirety of which are incorporated herein by reference.

### TECHNICAL FIELD

The present application relates to field of LED (Light Emitting Diode) displays, and more particularly to a splicing plate, a splicing plate component, a splicing display screen, a middle frame, and a light board assembly.

### RELATED ART

At present, display screens used in situations such as outdoor displays, large exhibitions, and conferences are typically composed of multiple small display units pieced together to form a larger screen. These display units work together under the control of a controller to achieve a synchronized display function. In some current splicing solutions, when two display units are spliced together, a splicing plate is required. However, the splicing plates in existing technology do not fit well with the display screen, resulting in difficulties in improving installation efficiency.

### SUMMARY

This application provides a splicing plate, which is used for splicing at least two middle frames. The middle frame has a front side for installing the display module and a rear side opposite to the front. The outer contour of the middle frame is rectangular, and each corner of the rectangular has a corner region. At least one corner region is provided with a splicing plate assembly zone for mating with the splicing plate. The splicing plate assembly zone includes a front assembly zone and a rear assembly zone located on the front and rear sides of the middle frame, respectively. Both the front and rear assembly zones are provided with splicing screw holes and positioning pin holes. The splicing plate includes a plate body, a splicing through hole, and positioning pins located on the plate body. The positioning pins are integrally formed with the plate body. The positioning pins are configured to mate with the positioning pin holes, while the splicing through hole and splicing screw hole are configured to mate with a first threaded fastener to secure the splicing plate to the middle frame.

### BRIEF DESCRIPTION OF THE DRAWINGS

The present invention will become more readily apparent to those ordinarily skilled in the art after reviewing the following detailed description and accompanying drawings, in which:

FIG. 1 is a structural schematic diagram of a middle frame provided in the first embodiment of this application;

FIG. 2 is a schematic diagram showing the splicing plate and the first threaded fastener in cooperation as provided in the first embodiment of this application;

FIG. 3 is another structural schematic diagram of a middle frame provided in the first embodiment of this application;

FIG. 4 is a schematic diagram of the splicing plate and the front assembly zone of the middle frame in cooperation as provided in the first embodiment of this application;

FIG. 5 is a schematic diagram showing the splicing plate and the first threaded fastener in cooperation as provided in the first embodiment of this application;

FIG. 6-1 is a schematic diagram of the middle frame, splicing plate, bracket, and the first connecting plate in cooperation as provided in the first embodiment of this application;

FIG. 6-2 is a schematic diagram of the middle frame, splicing plate, bracket, and the second connecting plate in cooperation as provided in the first embodiment of this application;

FIG. 7 is an exploded view provided in the first embodiment of this application;

FIG. 8 is a structural schematic diagram of the splicing display screen provided in the first embodiment of this application;

FIG. 9 is a schematic diagram of the display module and the middle frame in cooperation as provided in the first embodiment of this application;

FIG. 10 is a structural schematic diagram of the connecting rod of the second magnetic element provided in the first embodiment of this application;

FIG. 11 is a schematic diagram of the second magnetic element on the middle frame as provided in the first embodiment of this application;

FIG. 12 is a structural schematic diagram of the structure of the second magnetic element provided in the first embodiment of this application;

FIG. 13 is a schematic diagram of the back of the display module provided in the first embodiment of this application;

FIG. 14 is an exploded view of the display device provided in the first embodiment of this application;

FIG. 15 is a schematic diagram showing the middle frame and the back cover in cooperation as provided in the first embodiment of this application;

FIG. 16 is a schematic diagram showing the installation of the display support module on the middle frame as provided in the first embodiment of this application;

FIG. 17 is another exploded view of the display device provided in the first embodiment of this application;

FIG. 18 is an exploded view of the back cover provided in the first embodiment of this application;

FIG. 19 is a structural schematic diagram of the back cover provided in the first embodiment of this application;

FIG. 20 is an enlarged view of area Q in FIG. 19;

FIG. 21 is a three-dimensional assembly diagram of the splicing display screen provided in the second embodiment of this application;

FIG. 22 is a three-dimensional exploded schematic diagram of the splicing display screen provided in the second embodiment of this application;

FIG. 23 is an exploded structure diagram of the first middle frame structure provided in the second embodiment of this application;

FIG. 24 is an exploded structure diagram of the second middle frame structure provided in the second embodiment of this application;

FIG. 25 is a schematic diagram of the splicing structure of the middle frame provided in the second embodiment of this application;

FIG. 26 is an exploded structure diagram of the first electrical interface component provided in the second embodiment of this application;

FIG. 27 is a structural schematic diagram when the first electrical interface component is disconnected from the second electrical interface component as provided in the second embodiment of this application;

FIG. 28 is a schematic diagram of a three-dimensional structure from another angle of the first electrical interface component provided in the second embodiment of this application;

FIG. 29 is a structural schematic diagram when the first electrical interface component is connected to the second electrical interface component as provided in the second embodiment of this application;

FIG. 30 is a schematic diagram of a three-dimensional structure of the movable part of the first electrical interface component provided in the second embodiment of this application;

FIG. 31 is a schematic diagram of a three-dimensional structure of the operating component of the first middle frame provided in the second embodiment of this application;

FIG. 32 is a schematic diagram of the positioning component provided in the second embodiment of this application;

FIG. 33 is a schematic diagram of a three-dimensional structure of the first electrical interface component in the first position of the positioning component as provided in the second embodiment of this application;

FIG. 34 is a schematic diagram of a three-dimensional structure of the first electrical interface component in the second position of the positioning component as provided in the second embodiment of this application;

FIG. 35 is a structural schematic diagram of the middle frame of the display module provided in the third embodiment of this application;

FIG. 36 is a cross-sectional view of the splicing of the middle frame provided in the third embodiment of this application;

FIG. 37 is a schematic diagram of the component structure of the display module provided in the third embodiment of this application;

FIG. 38 is an exploded view of the component structure of the display module provided in the third embodiment of this application;

FIG. 39 is another cross-sectional view of the splicing of the middle frame provided in the third embodiment of this application;

FIG. 40 is a schematic diagram of the assembly structure of the bottom beam of the middle frame provided in the third embodiment of this application;

FIG. 41 is a schematic diagram of the installation of the splicing display screen provided in the third embodiment of this application;

FIG. 42 is a schematic diagram showing the position of the first and second fixing holes on the middle frame provided in the third embodiment of this application;

FIG. 43 is a schematic diagram showing the position of the first adjustment hole on the middle frame provided in the third embodiment of this application;

FIG. 44 is a schematic diagram showing the position of the second adjustment hole on the middle frame provided in the third embodiment of this application;

FIG. 45 is a structural schematic diagram of the middle frame of the display module provided in the third embodiment of this application;

FIG. 46 is an exploded view of the light board component provided in the first embodiment of this application;

FIG. 47 is a front projection view of the back of the light board component provided in the first embodiment of this application;

FIG. 48 is a cross-sectional view along line A-A in FIG. 47;

FIG. 49 is an exploded view of the structure shown in FIG. 48;

FIG. 50a is a schematic diagram of the compression of the light board and the support component provided in the first embodiment of this application;

FIG. 50b is another schematic diagram of the compression of the light board and the support component provided in the first embodiment of this application;

FIG. 51 is an exploded view of the light board component from another angle provided in the first embodiment of this application; and

FIG. 52 is a front projection view of the installation surface of the light board provided in the first embodiment of this application.

### DETAILED DESCRIPTION

To facilitate understanding of this application, a more comprehensive description of the application will be provided below with reference to the accompanying drawings. The accompanying drawings show the preferred embodiments of this application. However, this application can be implemented in many different forms and is not limited to the embodiments described herein. On the contrary, the provision of these embodiments aims to make the disclosed content of this application more thoroughly and comprehensively understood.

Unless otherwise defined, all technical and scientific terms used herein have the same meaning as commonly understood by those skilled in the art to which this application belongs. The terminology used herein is solely for the purpose of describing specific embodiments and is not intended to limit the application.

### First Embodiment

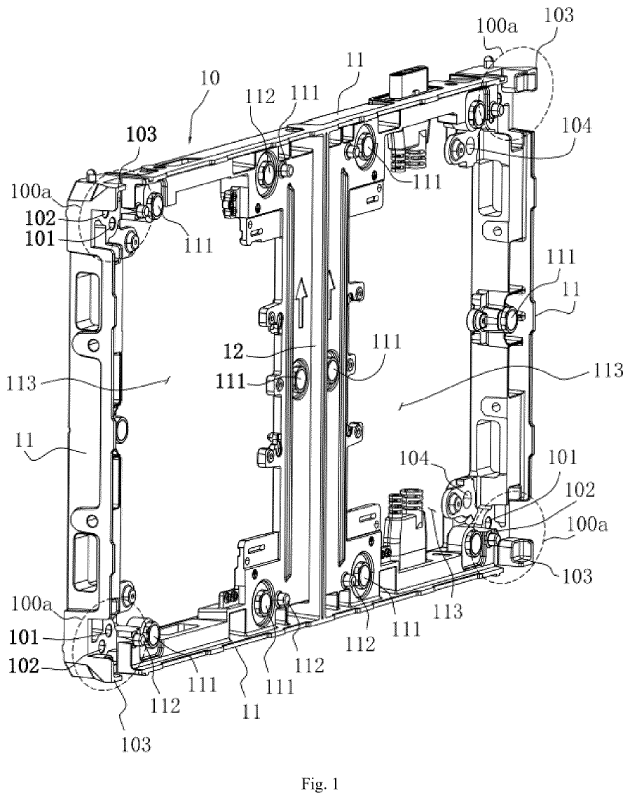

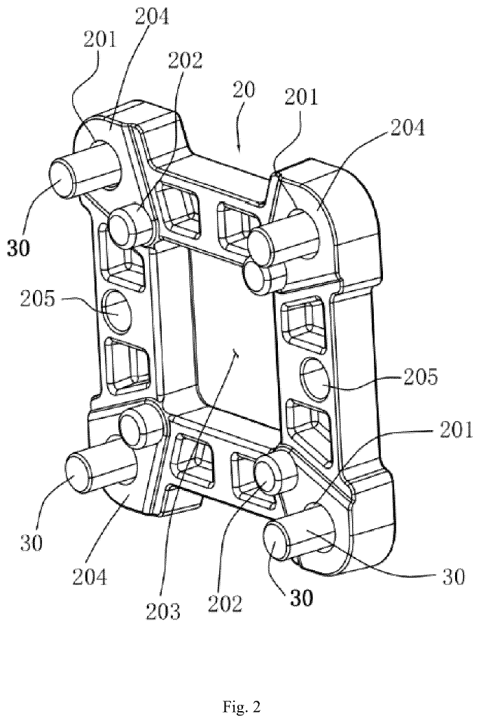

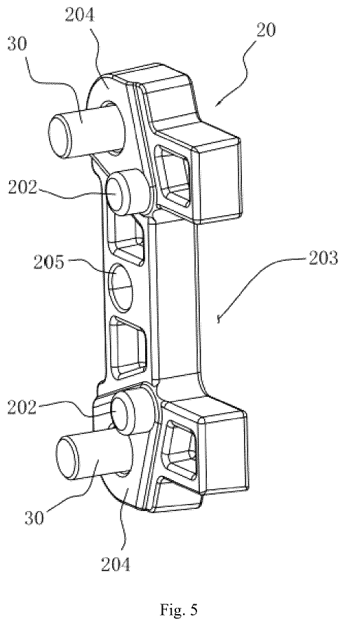

In response to the issue of insufficient compatibility between the splicing plate and the middle frame in existing technology, which leads to difficulties in improving installation efficiency, this embodiment provides a splicing plate. As shown in FIGS. 2 and 5, the splicing plate 20 is used to splice at least two middle frames together, with the structure of the middle frame 10 shown in FIG. 1.

In this embodiment, the middle frame 10 can also be referred to as a “box,” serving as the mounting carrier for key components such as the display module or the display panel, a power supply, and a signal transfer card within the display device. It has high strength and load-bearing capacity. For example, in some examples, the middle frame 10 is made of metal or alloy. The middle frame 10 is a frame structure with four side beams 11. The four side beams 11 are connected end-to-end, forming a rectangular outer contour of the middle frame 10. The rectangular middle frame 10 has four vertices, corresponding to four corner regions. In this embodiment, the area corresponding to the corners is referred to as the “corner region.” At least one of the four corner regions of the middle frame 10 is equipped with a splicing plate assembly zone for cooperation with the splicing plate 20. The splicing plate 20 is used to splice at least two middle frames 10 together using at least two first threaded fasteners 30. Therefore, when splicing the middle frames 10, the splicing plate 20 connects and secures at least two middle frames 10 simultaneously. In this embodiment, the side of the middle frame 10 used for mounting the display module is referred to as the front side of the middle frame 10, while the opposite side is referred to as the rear side of the middle frame 10. Typically, the rear side of the middle frame 10 is where the back cover of the display device can be mounted.

In this embodiment, the splicing plate 20 includes a sheet-like body and is equipped with splice through-holes and positioning pins on the sheet body. Refer to FIG. 2, which provides a schematic diagram of the connection between the splicing plate 20 and the first threaded fastener 30. The splicing plate 20 is configured with at least two non-threaded splice through-holes 201 corresponding to at least two middle frames 10. For details on the middle frame, refer to FIG. 1. In FIG. 2, the splicing plate 20 is approximately rectangular in shape and features four splice through-holes 201 located at the four corners of the splice piece. Each splice through-hole 201 corresponds to a middle frame 10. Consequently, the splicing plate 20 illustrated in FIG. 2 can connect four middle frames 10 together.

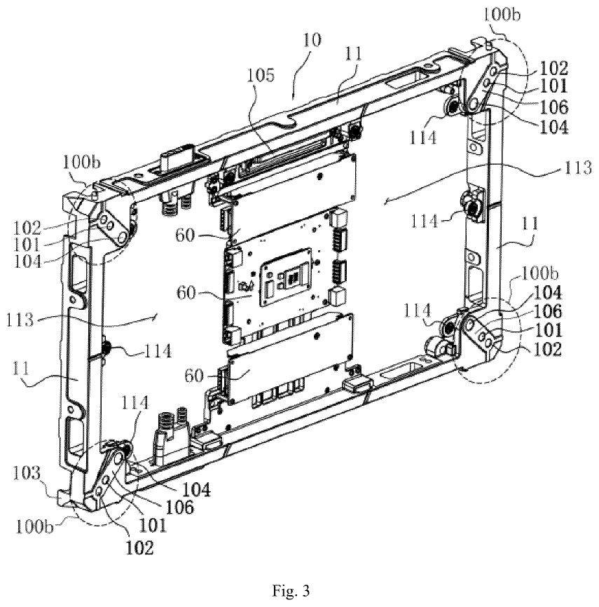

In the splicing plate assembly zone, there are splicing screw holes 101 shown in FIGS. 1 and 3. The splicing screw holes 101 penetrate through the front and rear sides of the middle frame 10. The splicing screw holes 101 correspond one-to-one with the splicing through holes 201. Both of these work in conjunction with the first threaded fastener 30. One end of the first threaded fastener 30 passes through the splicing through hole 201 and is tightly screwed into the splicing screw hole 101 on the middle frame 10 through a threaded connection, thus achieving a tight connection between the splicing plate 20 and the middle frame 10.

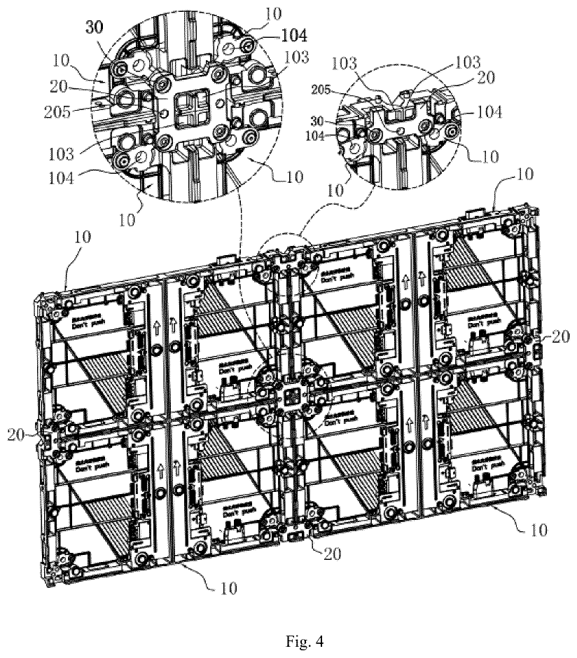

In this embodiment, as shown in the locations indicated by the dashed boxes in FIGS. 1 and 3, the splicing plate assembly zone includes a front assembly zone 100a on the front side of the middle frame 10 (shown by the dashed box in FIG. 1) and a rear assembly zone 100b on the rear side of the middle frame 10 (shown by the dashed box in FIG. 3). The front assembly zone 100a and the rear assembly zone 100b are located to be opposite to each other. In this embodiment, when splicing the middle frame 10, the splicing plate 20 can be placed on the front side of the middle frame 10 to cooperate with the front assembly zone 100a (refer to FIG. 4), or it can be placed on the rear side to cooperate with the rear assembly zone 100b (refer to FIGS. 6-1 and 6-2). In some examples, splicing plates 20 can even be installed simultaneously in both the front assembly zone 100a and the rear assembly zone 100b of the middle frame 10. However, typically, only one side of the splicing plate assembly zone needs to cooperate with the splicing plate 20.

Referring to FIGS. 1 to 3, it can be understood that when the splicing plate 20 is in conjunction with the front assembly zone 100a, the splicing plate 20 is located on the front side of the middle frame 10. This is suitable for the installation scenario where the installation personnel can access the display module from the front side of the middle frame 10. In this case, one end of the first threaded fastener 30 can be sequentially inserted through the splicing through hole 201 and engaged with the splicing screw hole 101 on the front side of the middle frame 10 via a threaded connection (refer to FIGS. 1 and 4). When the splicing plate 20 is in conjunction with the rear assembly zone 100b, the splicing plate 20 is located on the rear side of the middle frame 10. This is suitable for the installation scenario where the installation personnel can access the display module from the rear side of the middle frame 10. In this case, one end of the first threaded fastener 30 can be sequentially inserted through the splicing through hole 201 and engaged with the splicing screw hole 101 on the rear side of the middle frame 10 via a threaded connection (refer to FIGS. 3, 6-1, and 6-2).

Continuing to refer to FIG. 1, in some examples, the front assembly zone 100a is at least partially recessed. When the splicing plate 20 is in conjunction with the front assembly zone 100a, a portion of the splicing plate 20 can be embedded into the recess of the front assembly zone 100a, which can reduce the overall thickness after the splicing plate 20 is connected to the middle frame 10. This can avoid the splicing plate 20 protruding excessively on the front side of the middle frame 10, which would interfere with the installation of the display module on the front side of the middle frame 10. In some examples, the recess depth of the front assembly zone 100a is greater than or equal to the thickness of the splicing plate 20, so that the splicing plate 20 does not protrude from the front side of the middle frame 10. It should be understood that, in any case, the splicing plate 20 will not be completely embedded into a single middle frame 10 because a splicing plate 20 must work in conjunction with at least two middle frames 10 simultaneously. Therefore, only a portion of the splicing plate 20 will be embedded into each middle frame 10, while there will always be a part that is exposed outside the middle frame 10. However, from the perspective of the thickness direction of the splicing plate 20, its embedded part can be completely embedded into the middle frame 10.

Refer to FIGS. 1 to 3. In some examples, the splicing piece assembly region of the middle frame 10 is equipped with positioning pin holes 102, which are designed to fit with the positioning pins 202 on the splicing piece 20. It can be understood that this pin-hole fitting is simple, requires no tools, and is easy to implement. When the splicing piece 20 is aligned with the splicing piece assembly region 100 on the middle frame 10, the positioning pin holes 102 and the positioning pins 202 complete the pin-hole fitting. This means the positioning pins 202 are already inserted into the positioning pin holes 102. At this stage, the first threaded fasteners 30 have not yet engaged with the splicing threaded holes 101 and the splicing through-holes 201. Therefore, the pin-hole fitting allows for the preliminary fixation, or “pre-fixation,” of the splicing piece 20 onto the assembly connection region 100 before the middle frame 10 and the splicing piece 20 are fully locked. Once the pin-hole fitting is achieved, the splicing through-holes 201 align with the splicing threaded holes 101, facilitating the engagement of the first threaded fasteners 30 with the splicing piece 20 and the middle frame 10. In this embodiment, the precision of the pin-hole fitting is higher than that of the threaded fitting. For instance, in this case, the gap between the positioning pin holes 102 and the positioning pins 202 is 0.15 mm, while the gap between the first threaded fasteners 30 and the splicing threaded holes 101 is 0.5 mm. Since the role of the first threaded fasteners 30 and the splicing threaded holes 101 is to axially lock the splicing piece 20 to the middle frame via the fasteners, their assembly precision can be lower than that of the positioning pin holes 102 and the positioning pins 202. This design makes it easier to screw the first threaded fasteners 30 into the splicing threaded holes 101 during assembly, allowing for quicker installation.

In some examples, the plate body of the splicing plate 20 and the positioning pins 202 can be integrally formed, such as by die casting. It can be understood that the integrally formed process can significantly enhance the quality of the splicing plate 20, for example, in one example, the positioning pins 202 are integrally formed with the plate body, and the diameter of the positioning pins 202 reaches more than 8 mm, so as to ensure that the plate body and the positioning pins 202 can withstand a pressure of more than 500 kg.

In this embodiment, the positioning pin holes 102 set in the splicing plate assembly zone 100 can be blind holes or through holes. If they are blind holes, then the positioning pin holes 102 corresponding to the front assembly zone 100a and the rear assembly zone 100b are necessarily independent of each other. If the positioning pin holes 102 are through holes, meaning the corresponding positioning pin holes 102 of the front assembly zone 100a and the rear assembly zone 100b are connected, then the positioning pin holes 102 corresponding to the front assembly zone 100a and the rear assembly zone 100b can be the same. In some examples, in order to reduce the number of holes in the splicing plate assembly zone 100 and maintain the load-bearing capacity of the splicing plate assembly zone 100, a single positioning pin hole 102 can be shared between the front assembly zone 100a and the rear assembly zone 100b. In this case, one end of the positioning pin hole 102 facing the front side of the middle frame 10 allows for the insertion of the positioning pin 202 from the front side of the middle frame 10, while the other end allows for the insertion of the positioning pin 202 from the rear side of the middle frame 10.

Please continue to refer to FIGS. 1 and 2. In some examples, a corner protrusion 103 is arranged between the rectangular vertices corresponding to the front assembly zone 100a and its associated corner region. Correspondingly, in the splicing plate 20 that works in conjunction with the front assembly zone 100, a first limiting slot 203 is provided for the corner protrusion 103 to pass through. The first limiting slot 203 runs through the splicing plate 20. When a splicing plate 20 is combined with the front assembly zone 100a, the corner protrusion 103 will pass through the first limiting slot 203 on the splicing plate 20. When the splicing plate 20 is embedded into the front assembly zone 100a, the corner protrusion 103 will extend into the first limiting slot 203, allowing the splicing plate 20 to fit over the corner protrusions 103 of the four middle frames 10. This achieves pre-fixation between adjacent middle frames 10 in the direction parallel to the display surface, ensuring that the four middle frames 10 will not separate from each other in the direction parallel to the display surface.

Additionally, since the display module needs to be installed on the front side of the middle frame 10, when the front assembly zone 100a is recessed toward the rear side of the middle frame 10, the corner protrusion 103 is arranged between the rectangular vertices corresponding to the front assembly zone 100a and its associated corner region. This avoids the entire corner region of the middle frame 10 being recessed, which would otherwise cause a lack of support for the corner regions of the display module installed on the front side of the middle frame 10. By setting the corner protrusion 103, the support capability of the middle frame 10 for the display module on its front side is enhanced, and the flatness of the display surface of the display device or splicing display screen formed by the middle frame 10 is improved.

It should be noted that although the first limiting slot 203 of the splicing plate 20 shown in FIG. 2 is located in the middle part of the splicing plate 20 and surrounded on all sides by the body of the splicing plate 20, in some other examples of this embodiment, the splicing plate 20 can have other structures. For example, in FIG. 5, which shows another schematic diagram of the splicing plate 20 in conjunction with the first threaded fastener 30, the body of the splicing plate 20 does not form a closed ring, and the first limiting slot 203 is not completely surrounded by the body of the splicing plate 20. It can be understood that the splicing plate 20 shown in FIG. 2 can be used to splice four middle frames 10, while the splicing plate 20 shown in FIG. 5 can be used to splice two middle frames 10. In the entire splicing display screen, different shapes of splicing plates 20 can be selected according to the splicing position. Referring to FIG. 4, the splicing plate 20 with two first threaded fasteners 30 shown in FIG. 5 can be used in the peripheral area of the splicing display screen, while the splicing plate 20 with four first threaded fasteners 30 shown in FIG. 2 can be used in other areas of the splicing display screen.

Refer to FIGS. 2 and 5. In some examples, during assembly, the plane of the splicing piece 20 that contacts the splicing piece assembly region 100 is the plane of the bosses 204 formed on the splicing piece 20. The splicing piece 20 includes at least two bosses 204, with each boss 204 having a plane at the same horizontal level. Similarly, the planes on the corresponding middle frame 10 that contact the bosses 204 are also at the same horizontal level. When the corresponding bosses 204 of the splicing piece 20 are tightly fitted with different middle frames 10, it ensures that all the middle frames 10 remain on the same overall plane. The bosses 204 have smooth planar surfaces, and correspondingly, the surfaces of the middle frames that contact and connect with the bosses 204 are also smooth planar surfaces. The splicing through-holes 201 are located on the bosses 204. Besides the smooth surfaces of the bosses 204, other surfaces of the splicing piece 20 can be relatively rough to reduce manufacturing costs. Similarly, surfaces of the middle frames 10, apart from those that contact the bosses 204, can also be relatively rough to lower production expenses. In this embodiment, as shown in FIG. 3, each assembly region 100b on the rear side of the middle frame is equipped with a boss 106 corresponding to the boss 204 of the splicing piece 20. Each boss 106 is at the same horizontal level and also has a smooth planar surface. These bosses 106 protrude from the rear side of the middle frame 10, facilitating grinding and machining to ensure all bosses 106 are at the same horizontal level. The bosses 204 of the splicing piece 20 and the bosses 106 on the rear side of different middle frames work together to ensure the flatness of multiple middle frames after assembly. It should be understood that similar bosses to those described as 106 can also be provided in the assembly regions 100a on the front side of the middle frames.

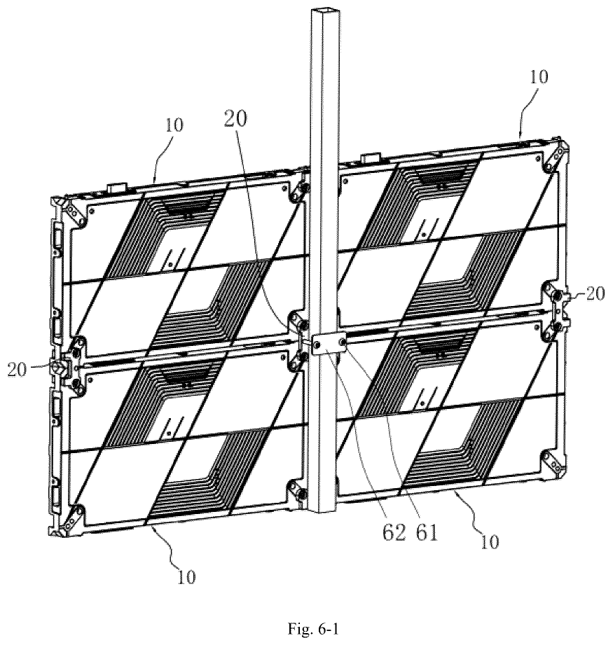

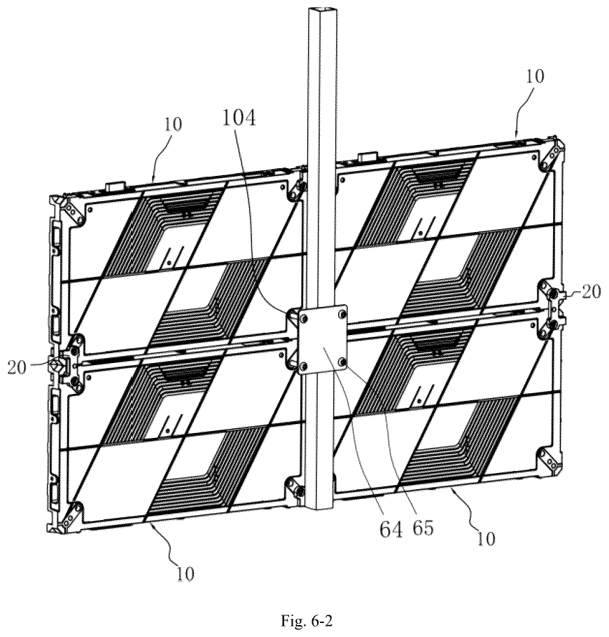

Please continue to refer to FIG. 1 to FIG. 6-2. In some examples, installation personnel could assemble and splice the middle frames 10 from the front side to form a splicing display screen, which can be briefly called “front installation.” In this case, the installation personnel can first install the splicing plates 20 on the front side of the middle frames 10 without installing the display modules, and complete the locking of the splicing plates 20 and the middle frames 10 with the first threaded fasteners 30, thus completing the splicing of multiple middle frames 10. On the other hand, installation personnel can use the second connecting plate 64 (refer to FIG. 6-2) and the second external fastener 65 to install the middle frames 10 onto the mounting bracket 63 (i.e., the mounting carrier) by placing the multiple middle frames 10 to be fixed on the front side of the mounting bracket 63, placing the second connecting plate 64 on the back side of the mounting bracket 63, and then inserting one end of the second external fastener 65 from the front side of the middle frame 10 through the external fixing hole 104 set in the corner region of the middle frame 10. After passing through the external fixing hole 104 (refer to FIG. 4), the end of the second external fastener 65 enters the second connecting hole on the second connecting plate 64. The external fixing hole 104 is a through hole (without threads), while the second connecting hole is either a threaded hole or a through hole. The second external fastener 65 can be but is not limited to threaded fasteners such as bolts. The second external fastener 65 is fixed by threaded connection through the second connecting hole or fixed by a nut through the second connecting hole, thus achieving the fixation of the mounting bracket 63 and the middle frame 10. After tightening, the middle frame 10 and the second connecting plate 64 will clamp the mounting bracket 63 therebetween. After the fixation of the middle frames 10 is completed, installation personnel can install the display modules from the front side of the middle frames 10, thereby obtaining a splicing display screen fixed on the mounting bracket 63. In another example, the mounting carrier can be changed from a mounting bracket 63 to a wall with load-bearing capability. In this case, the external fixing holes 104 on the middle frames 10 can be fitted with a third fastener. The third fastener can be a self-tapping screw, expansion bolt, or other threaded fastener. One end of the third fastener passes through the external fixing holes 104 on the middle frames 10 and into the wall, thereby fixing the middle frames 10 directly onto the wall.

In some examples, the external fixing holes 104 and the splicing plate assembly zones 100 are located in the same corner region. In other cases, they can be distributed in different corner regions. In some examples, the four corner regions of the middle frames 10 all have splicing plate assembly zones 100 and external fixing holes 104. In this case, whether for splicing the middle frames 10 or for installing the middle frames 10 onto an external wall or bracket, there is no need to distinguish the arrangement positions of the middle frames 10, which helps improve the efficiency of the installation personnel and reduce the operational burden.

In this embodiment, the installation personnel could assemble and splice the middle frames 10 from the rear side to form the splicing display screen, which can be briefly called “rear installation.” In this case, the middle frames 10 do not rely on the external fixing holes 104 to achieve fixation on the mounting bracket 63 but instead utilize the third connecting holes 205 with internal threads set on the splicing plates 20. The splicing plates 20 not only splice the multiple middle frames 10 together but also fix the splicing plates 20 to the external first connecting plate 62 through the third connecting holes 205 with internal threads, thereby achieving the connection between the middle frames 10 and the first connecting plate 62. Referring to FIG. 2 and FIG. 6-1, first, the installation personnel can install the splicing plates 20 on the rear side of the middle frames 10 and use the first threaded fasteners 30 to complete the locking of the splicing plates 20 and the middle frames 10. Then, the installation personnel inserts one end of the first external fastener 61 (which can be but is not limited to a threaded fastener) through the first connecting hole on the first connecting plate 62 from the rear side. The first connecting hole is a through hole without threads. Afterwards, the installation personnel tightly connects it to the third connecting hole 205 with internal threads on the splicing plate 20, thereby completing the connection and fixation of the splicing plate 20 and the first connecting plate 62. In FIG. 6-1, the splicing plate 20 and the first connecting plate 62 are respectively positioned on the front and rear sides of the mounting bracket 63. In the rear installation method, the middle frames 10 do not need to connect with the first connecting plate 62 and do not need to have additional holes on the middle frames 10 for connecting to the first connecting plate 62, which can simplify the structure of the middle frames 10.

This embodiment also provides a splicing component, which includes the splicing plate provided in any of the previous examples. Additionally, this splicing component includes the first threaded fastener, the first connecting plate, the first external fastener, the second connecting plate, and the second external fastener. The splicing plate is used to splice several middle frames, such as two or four middle frames. The first connecting plate and the second connecting plate are then used to fix the spliced multiple middle frames or the splicing display screen formed after splicing onto the mounting carrier. It can be understood that when fixing the spliced middle frames onto a mounting carrier such as a mounting bracket, the selection of using either the first connecting plate or the second connecting plate is sufficient. For example, if the “rear installation” method is chosen, the first connecting plate is used; if the “front installation” method is chosen, the second connecting plate is used. In the “rear installation” method, the first connecting plate is paired with the splicing plate through the first threaded fastener, specifically, the first threaded fastener passes through the first connecting plate and then through the connecting hole on the splicing plate. In the “front installation” method, the second connecting plate is paired with the middle frame, specifically, the first threaded fastener passes through the external fixing hole on the middle frame from the front side and then through the second connecting plate. The splicing plate provided in this embodiment can be used for splicing the middle frames from the front side or the rear side. The splicing plate can be fitted with the positioning pin holes of the middle frame through the positioning pins, and the surface of the raised portions on the splicing plate are on the same horizontal plane and in tight contact with the middle frame, reducing the seams and improving the splicing flatness. Meanwhile, since the middle frame can be used for both front-side and rear-side splicing, the installation operation is simple, and the applicable scenarios are wide.

This embodiment provides a splicing display screen, which includes at least two spliced middle frames, at least two display modules, and at least two back covers. Each display module is respectively installed on the front side of each middle frame, and each back cover is respectively installed on the rear side of each middle frame.

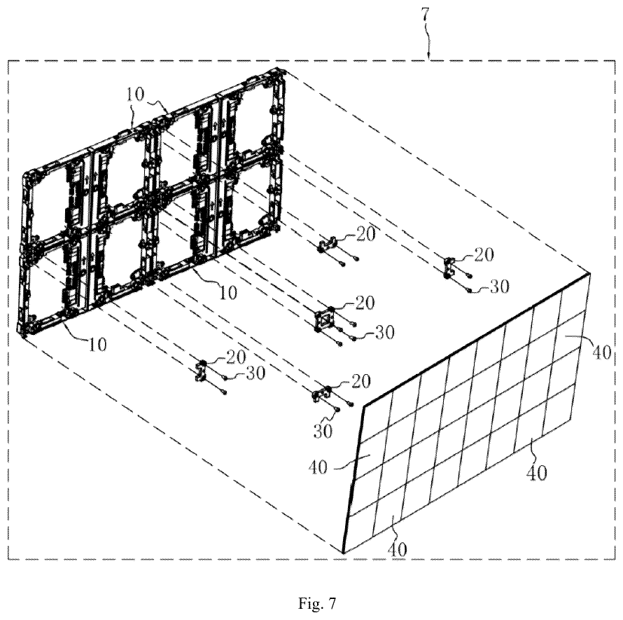

In this embodiment, the middle frame can be spliced together using, but not limited to, the splicing plates mentioned in the previous examples. For instance, refer to FIGS. 7 and 8. In the splicing display screen 7 includes splicing plates 20, at least two first threaded fasteners 30 and at least two middle frames 10. The middle frames 10 are fixed together with the splicing plates 20 by the first threaded fasteners 30. Therefore, by using the splicing plate 20 as a “bridge,” different middle frames 10 can be spliced together. In one splicing display screen 7, two or more splicing plates 20 with slightly different structures may be included. For example, in FIG. 7, some splicing plates 20 in the splicing display screen 7 can be used to splice four middle frames 10 together, while other splicing plates 20 may be used to splice only two middle frames 10. It is understandable that one splicing plate 20 corresponds to at least two middle frames 10, and at the same time, one middle frame 10 may correspond to at least two splicing plates 20.

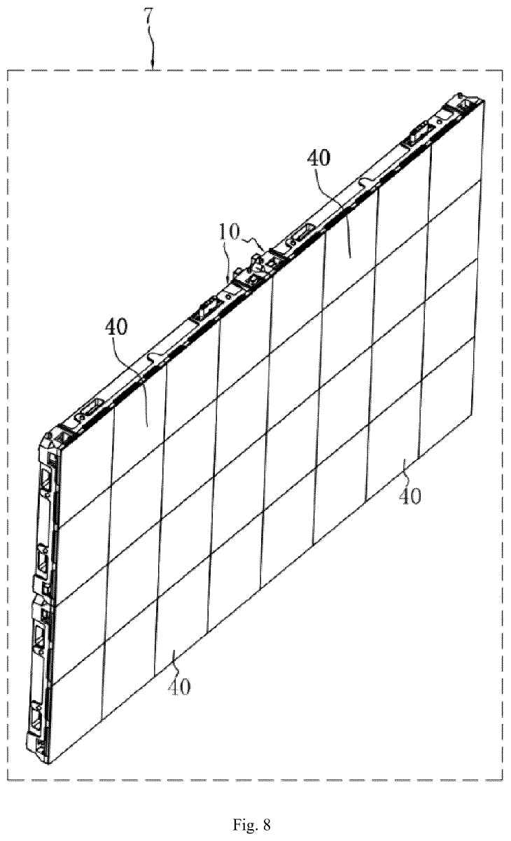

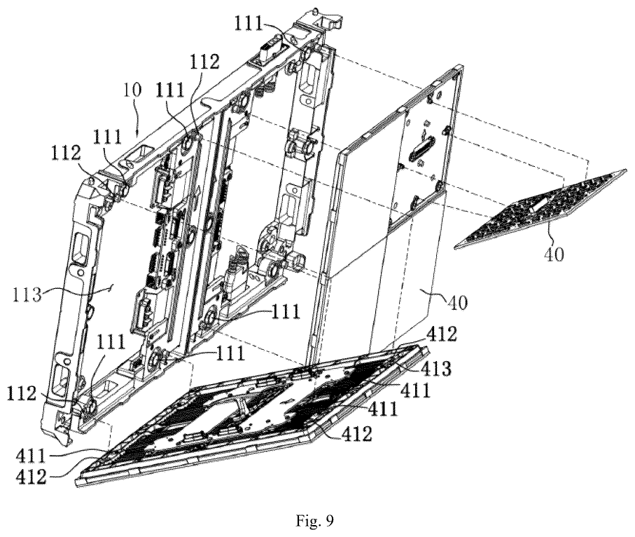

The splicing display screen 7 also includes multiple display modules 40, which are installed on the front side of the middle frame 10, as shown in FIG. 8. In some examples, the display modules 40 can be detachably fixed to the middle frame 10 through methods such as magnetic attraction, snapping, screwing, or even adhesion. For instance, please further refer to FIGS. 9 and 13. A first magnetic element 411 is arranged on the display module 40, and a second magnetic element 111 is arranged on the front side of the middle frame 10. When the display module 40 is assembled to the middle frame 10, the first magnetic element 411 and the second magnetic element 111 are positioned to be opposite to each other and are mutually attracted. It is understood that one of the first magnetic element 411 and the second magnetic element 111 can be a magnet, while the other can be a ferromagnetic metal; e.g., iron, cobalt, nickel. Alternatively, both can be magnets.

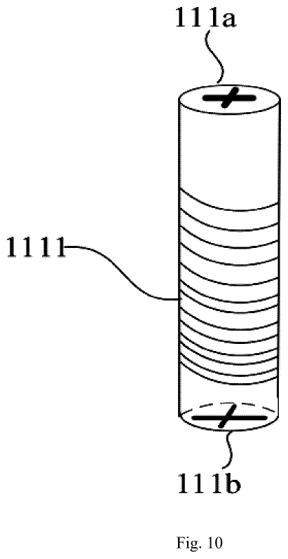

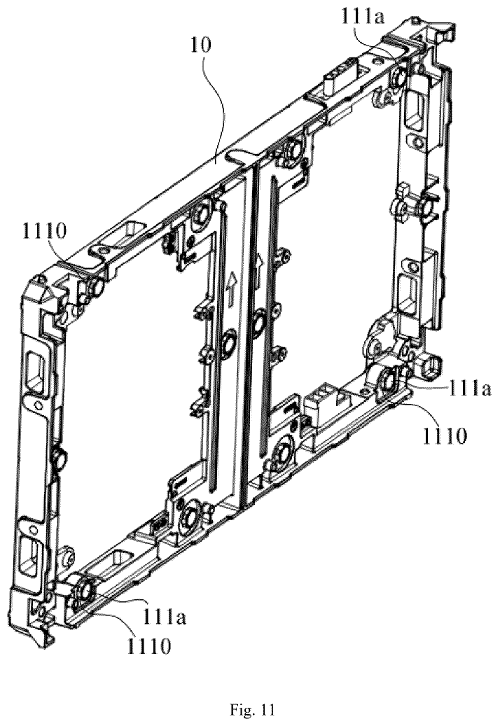

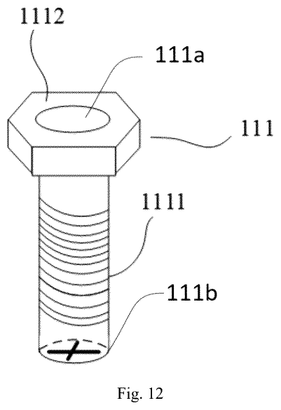

In some examples, the second magnetic element 111 includes a connecting rod 1111 and a magnetic disc 1112. Please refer to FIG. 10 or FIG. 12 for the second magnetic element 111. Functionally, the second magnetic element 111 has a magnetic front end 111a and a fixed rear end 111b, with the magnetic front end 111a and the fixed rear end 111b positioned at opposite ends of the connecting rod 1111. Please refer to FIG. 11. The middle frame 10 is provided with a magnetic element fixing hole 1110, into which the fixed rear end 111b is inserted, while the magnetic front end 111a is exposed on the front side of the middle frame 10 for matching with the first magnetic element 411 on the display module 40 (refer to FIGS. 9 and 13). The height at which the connecting rod 1111 is exposed on the front side of the middle frame 10 is referred to as the exposure height. In this embodiment, the exposure height is adjustable, meaning the distance between the magnetic front end 111a and the middle frame 10 can be adjusted. This allows the distance between the display module 40, which is connected to the magnetic front end 111a, and the middle frame 10 to be adjustable. With this design, after the middle frames 10 are spliced together to form the splicing display screen 7, the distance between each display module 40 and the middle frame 10 on the splicing display screen 7 can be flexibly adjusted. As a result, it ensures that the display surfaces of all display modules 40 are on the same plane, improving the overall display effect of the splicing display screen 7.

In this embodiment, the magnetic front end 111a includes a front operation section, which is designed to engage with external tools (screwdrivers, sockets, etc.) to allow the adjustment of the exposure height of the connecting rod 1111 from the front side of the middle frame 10. Therefore, if it is necessary to adjust the distance between a display module 40 and the middle frame 10, the installer can first remove the display module 40, then use an external tool to operate the front operation section, and after the adjustment is complete, reinstall the display module 40 onto the middle frame 10. In some examples, the fixed rear end 111b is at least partially exposed on the rear side of the middle frame 10. The fixed rear end 111b also includes an operation section for adjusting the exposure height of the connecting rod 1111, which corresponds to the front operation section and is referred to as the “rear operation section.” It should be understood that if the installer wishes to adjust the exposure height of the connecting rod 1111 using the rear operation section, the adjustment needs to be made from the rear side of the middle frame 10. In this case, the installer can choose not to remove the display module 40 and directly make the adjustment, making it convenient for the installer to immediately determine the difference between the display surface of the adjusted display module 40 and the display surfaces of the other display modules 40. Since the exposure height of the connecting rod 1111 in the second magnetic element 111 can be adjusted both from the front and rear sides of the middle frame 10, it allows the installer to flexibly choose the adjustment method based on the application scenario, improving the flatness of the display surface.

In some examples, the connecting rod 1111 is threaded with the magnetic element fixing hole 1110. The surface of the connecting rod 1111 is provided with external threads, while the inner wall of the magnetic element fixing hole 1110 is provided with internal threads, and both threads are matched, allowing the connecting rod 1111 to move axially within the magnetic element fixing hole 1110 through rotation. In some examples, the front operation section may be a recessed pattern on the magnetic front end 111a, and/or the rear operation section may be a recessed pattern on the fixed rear end 111b. The recessed pattern may include but is not limited to a slot-like pattern, a cross-shaped pattern, or star-shaped, pentagon-shaped, or hexagon-shaped non-circular patterns. Correspondingly, the external tool should have an end that can be inserted into and fit these recessed patterns. For example, the external tool could be a screwdriver. In other examples of this embodiment, the front operation section may be a non-circular profile on the end face of the magnetic front end 111a, and/or the rear operation section may be a non-circular profile on the end face of the fixed rear end 111b. The term “non-circular profile” refers to shapes such as triangular, rectangular, parallelogram, regular hexagonal, or regular octagonal shapes. Correspondingly, the external tool should have a recess with the shape and size that can match these end faces. For instance, the external tool could be a socket.

In some examples, as shown in FIG. 12, the second magnetic element 111, in addition to the connecting rod 1111, may also have a magnetic disk 1112. The magnetic disk 1112 is fixed to the end of the connecting rod 1111 near the magnetic front end 111a and can attract the first magnetic element 411. In this case, the magnetic front end 111a is effectively the end where the magnetic disk 1112 is located, and the magnetic function of the magnetic front end 111a is provided by the magnetic disk 1112. In some examples, the magnetic disk 1112 may be a magnet, and the surface area of the magnetic disk 1112's outer profile is larger than the surface area of the end of the connecting rod 1111 near the magnetic front end 111a. Therefore, through the magnetic attraction between the magnetic disk 1112 and the first magnetic element 411, the contact area between the second magnetic element 111 and the first magnetic element 411 is increased in comparison with the situation where only the magnetic front end 111a of the connecting rod 1111 attracts the first magnetic element 411. This increase in contact area enhances the mutual attraction between the two elements, thereby improving the reliability of the display module 40's attachment to the middle frame 10.

In some examples, a recessed pattern may be provided on the end face of the magnetic disk 1112 that is farther from the connecting rod 1111, forming a front operation section. This pattern may include, but is not limited to, a slot-like pattern, which allows the installer to use tools such as screwdrivers to rotate the magnetic disk 1112. This rotation causes the magnetic disk 1112 to drive the connecting rod 1111 to move along its axis. In other examples of this embodiment, the outer profile of the magnetic disk 1112 may be hexagonal or other non-circular shapes, which facilitates the installer using external tools like sockets to adjust the distance between the magnetic disk 1112 and the surface of the middle frame 10. In one example of this embodiment, the magnetic front end 111a of the second magnetic element 111 is equipped with a magnetic disk with a hexagonal outer profile, forming the front operation section. On the end face of the fixed rear end 111b, there is a recessed pattern designed for screwdriver operation, forming the rear operation section, as shown in FIG. 12. In another example, both ends of the connecting rod 1111 of the second magnetic element 111 are equipped with magnetic disks 1112 that have non-circular outer profiles. Additionally, the end face of the magnetic disk 1112 that is farther from the connecting rod 1111 is also provided with a recessed pattern.

In some examples, the display module 40 can be fitted to the middle frame 10 through a pin-hole structure. For instance, refer to FIGS. 9 and 13. A second pin-hole connector 112 is provided on the front side of the middle frame 10, and a first pin-hole connector 412 is provided on the back side of the display module 40. In the example corresponding to FIG. 9, the second pin-hole connector 112 can be a pin, and the first pin-hole connector 412 can be a pin hole. It is understood that in other examples of this embodiment, the specific implementation of the first pin-hole connector 412 and the second pin-hole connector 112 may be interchanged. However, as shown in FIG. 9, the pin is placed on the middle frame 10, and only a pin hole is provided on the display module 40. This design ensures the flatness of the surface of the display module 40, making it easier for the packaging and transportation of the display module 40.

In some examples, as shown in FIG. 13, the back side of the display module 40 is also equipped with a fixing ring 413. A fixing rope (not shown) that cooperates with the fixing ring 413 can be tied to the fixing ring 413 on the one hand, and can be tied to the middle frame 10 on the other hand. In this way, even if severe disasters such as earthquakes or hurricanes occur in the environment in which the splicing display screen 7 is located, the display module 40 will not easily fall off from the middle frame 10, preventing damage to the display module 40 caused by falling and further eliminating the risk of injury from the falling display module 40. This setup helps protect both property and safety of personnel.

In this embodiment, each display module 40 of the splicing display screen 7 can be mounted onto the middle frame 10 using magnetic attraction. This method facilitates installation and removal, reducing the burden of assembling and disassembling the splicing display screen 7, and helps improve the installation efficiency of the splicing display screen 7. Additionally, since the exposure height of the connecting rod 1111 in the second magnetic element 111, which interfaces with the display module 40 on the middle frame 10, is adjustable, it ensures that after the middle frames 10 are spliced together, the display surfaces of all the display modules 40 remain on the same plane, thereby enhancing the display effect. Furthermore, in this embodiment, the exposure height of the connecting rod 1111 in the second magnetic element 111 can be adjusted from both the front and rear sides of the middle frame 10, allowing installers to flexibly choose the adjustment method based on the application scenario of the splicing display screen 7, thus improving the flatness of the display surface.

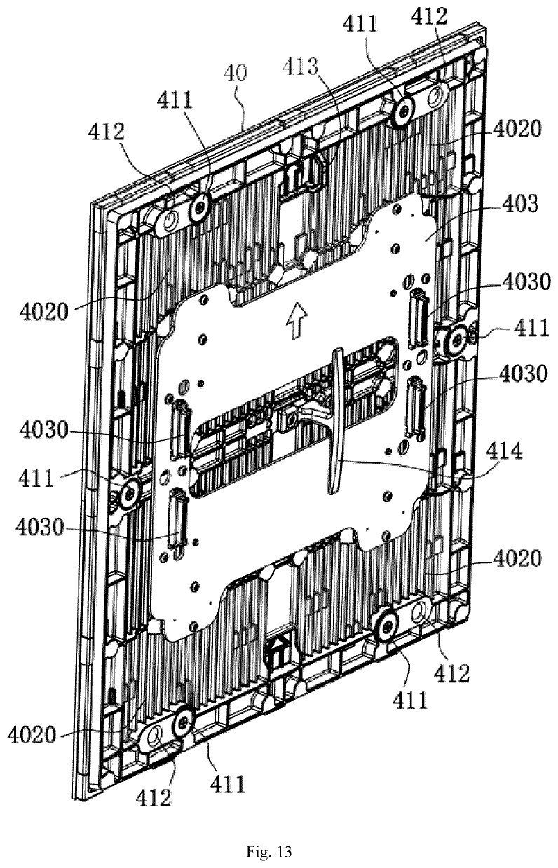

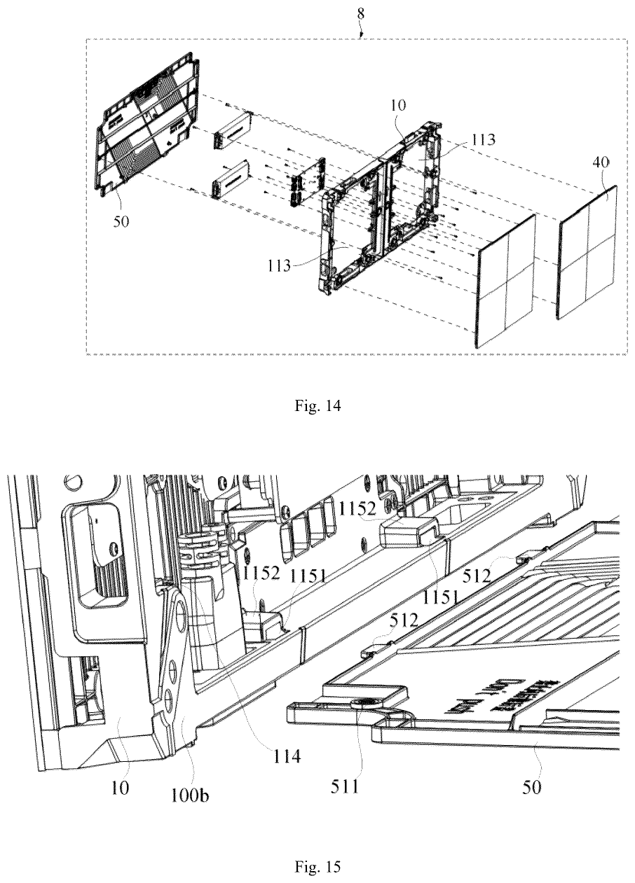

To make it easier to understand, this embodiment will be introduced from the perspective of the display device 8. The display device 8 in this embodiment includes a middle frame 10 and display modules 40. Typically, one middle frame 10 corresponds to two display modules 40, but configurations with fewer or more display modules 40 on one middle frame 10 are not excluded. In some examples, the display device 8 also includes a back cover. As shown in the exploded view of the display device 8 in FIG. 14, the back cover 50 is installed on the rear side of the middle frame 10 and is used to support the display modules 40 in the display device 8 from the rear side of the middle frame 10. The support module in this embodiment refers to modules that provide the necessary support for the display of the display module 40. The support module includes but is not limited to at least one of the power supply and signal adapter board. The back cover 50 conceals the back of the display module 40, enhancing the aesthetic appeal of the display device 8 on the one hand and on the other hand serving functions such as moisture-proofing and dust-proofing.

In some embodiments, the back cover 50 can be fixed to the middle frame 10 through methods such as screwing, snapping, or even adhesion. In other examples of this embodiment, the back cover 50 can be attached to the middle frame 10 using magnetic attraction, similar to how the display module 40 is attached. For instance, as shown in FIG. 15, a fourth magnetic element 114 is provided on the middle frame 10, and a third magnetic element 511 is provided on the back cover 50 to match with the fourth magnetic element 114. When the back cover 50 is assembled to the middle frame 10, the third magnetic element 511 and the fourth magnetic element 114 are positioned to be opposite to each other and attract each other. It is understood that one of the third magnetic element 511 and the fourth magnetic element 114 may be a magnet, while the other may be a metal with ferromagnetic properties, or both may be magnets.

In some examples, the installation of the back cover 50 onto the middle frame 10 does not affect the rear assembly zone 100b on the rear side of the middle frame 10. The middle frame 10 includes a back cover shielding zone, which refers to the area of the middle frame 10 that is covered by the back cover 50 after it is installed. In this embodiment, the back cover shielding zone does not overlap with the splicing plate assembly zone on the middle frame 10. As shown in the examples in FIG. 6-1 and FIG. 15, the back cover 50 can be embedded into the middle frame 10 and covers the area enclosed by the side beams of the middle frame 10. The four corners of the back cover 50 have corresponding notches, and when the back cover 50 is installed, it does not obstruct the rear assembly zone 100b. Therefore, if multiple middle frames 10 (or display devices 8) are spliced together using splicing plates 20 in the rear assembly zone 100b, the splicing plates 20 will not interfere with the installation of the back cover 50 on the middle frame 10.

In some examples, one side of the back cover 50 is equipped with an outwardly protruding locking tab 512, as shown in FIG. 15, where the locking tab 512 is positioned on the bottom edge of the back cover 50. The corresponding bottom side beam of the middle frame 10 is also equipped with a locking tab groove 1151 that accommodates the locking tab 512. The locking tab groove 1151 extends in a direction away from the back cover 50, and a shielding section 1152 is provided above part of the opening of the locking tab groove 1151. The shielding section 1152 protrudes from the beam, creating a space above the locking tab groove 1151 where the locking tab 512 can be inserted in parallel with the groove opening and beneath the shielding section 1152. The portion of the groove opening not covered by the shielding section 1152 allows the locking tab 512 to be inserted into the locking tab groove 1151. The locking tab 512 can be inserted into the accommodating space in a direction roughly parallel to the groove opening of the locking tab groove 1151. The internal space of the locking tab groove 1151 allows the locking tab 512 to rotate with the back cover 50 from a position parallel to the groove opening to a position perpendicular to the groove opening. This means the internal space of the locking tab groove 1151 allows the back cover 50 to rotate the locking tab 512 from a direction perpendicular to the display surface of the display device 8 to a direction parallel to the display surface.

When the back cover 50 is assembled to the middle frame 10 using the third magnetic element 511 and the locking tab 512, the back cover 50 can be easily removed or installed from the rear side of the middle frame 10. The whole process is very simple and easy to do. The back cover 50 does not need to have screw holes or anything to match with the middle frame 10, which helps improve the processing efficiency of the back cover 50 and keeps it looking clean and intact. When installing the back cover 50, the installer can place it vertically against the display surface and insert the locking tab 512 into the locking tab groove 1151, allowing for quick positioning of the back cover 50 onto the middle frame 10. Then, the installer simply rotate the back cover 50 until it is parallel to the display surface, making sure the third magnetic element 511 on the back cover 50 accurately snaps onto the fourth magnetic element 114 on the middle frame 10, and thereby the rapid installation of the back cover 50 is achieved. This ensures quick installation without the need to manually align the third magnetic element 511 and the fourth magnetic element 114, making the whole process faster and smoother. On the other hand, once the locking tab 512 is inserted into the locking tab groove 1151, the side beam of the middle frame 10, the locking tab groove 1151, and the shielding section 1152 all provide a bit of support and limitation for the back cover 50. This makes the connection between the back cover 50 and the middle frame 10 more reliable.

In some examples, the middle frame 10 is provided with a hollowed-out area 113 with dimensions that allow the display module 40 to pass through both the front and rear sides. For instance, if the hollowed-out area 113 is rectangular, the diagonal of the rectangular must be at least larger than the shorter edge of the display surface of the display module 40. In some cases, if the hollowed-out area 113 is rectangular, the length of its longer side is also larger than the shorter edge of the display surface of the display module 40. However, as understood by those skilled in the art, due to the presence of structures such as the splicing plate assembly zone in the corner regions of the middle frame 10, the hollowed-out area 113 is generally not a standard rectangular. Nonetheless, in such cases, the length of the line connecting at least two points on the contour of the hollowed-out area 113 is greater than the shorter edge of the display surface of the display module 40. Because the dimensions of the hollowed-out area 113 allow the display module 40 to pass through both the front and rear sides of the middle frame 10, once the display module 40 on the front side of the middle frame 10 is removed, it can pass through the hollowed-out area 113 to reach the rear side of the middle frame 10.

In some examples, the middle frame 10 is formed by four side beams enclosing a single hollowed-out area 113. However, in other examples of this embodiment, in addition to the four side beams, the middle frame 10 also includes at least one middle beam 12. Please refer to FIG. 1, where the four side beams 11 are connected end-to-end, and the vertical projection of these four side beams 11 on the display surface forms a roughly rectangular outline. One middle beam 12 has its two ends connected to two opposing side beams 11. In this way, the middle beam 12 divides the area enclosed by the side beams 11 into two hollowed-out areas 113. If there is more than one middle beam 12 in the middle frame 10, it can be divided into more than two hollowed-out areas 113. In some examples, the middle beams 12 are arranged to be parallel to each other. In other examples, some of the middle beams 12 may be perpendicular to each other. The middle frame 10 includes two middle beams 12 arranged perpendicularly, forming a “cross” shape, with the middle frame 10 containing four hollowed-out areas 113.

In this embodiment, the display module 40 supports both front-side and rear-side disassembly from the middle frame 10. Taking the disassembly of the display module 40 as an example, and referring to FIG. 14 and FIG. 15, when the display module 40 is installed on the middle frame 10 using magnetic attachment, the installer can directly use a suction tool from the front side to remove the display module 40. Alternatively, the installer can first remove the back cover 50 from the rear side of the middle frame 10, and then apply pressure to the display module 40 from the rear side of the middle frame 10, causing the display module 40 to detach from the middle frame 10. However, during this process, the display module 40 remains under the installer's control. It remains held by the installer or is still connected to a disassembly tool controlled by the installer. Subsequently, the installer positioned at the rear side of the middle frame 10 can rotate the display module 40 and move it in such a way that the display module 40 passes through the hollowed-out area 113 of the middle frame 10, thereby completing the disassembly from the rear side of the middle frame 10.

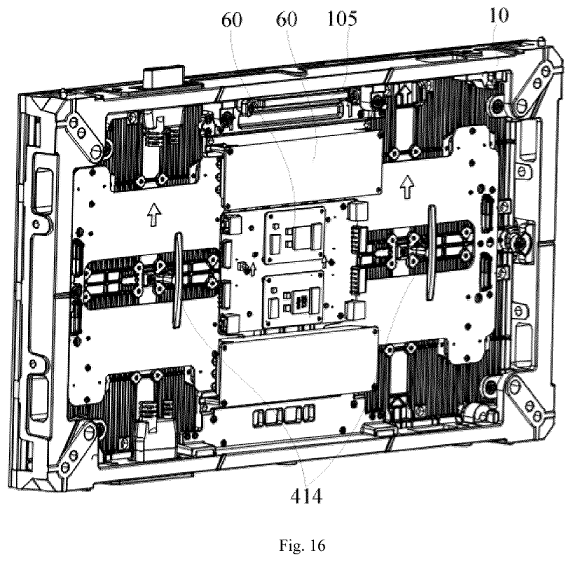

In some examples, to facilitate the disassembly of the display module 40 from the rear side of the middle frame 10, a module gripping part may be provided on the rear side of the display module 40. Please refer to FIG. 13 and FIG. 16 for a schematic diagram showing one structure of the display module 40. The rear side of the display module 40 is equipped with a handle, which serves as the module gripping part 414. When the installer is disassembling or assembling the display module 40 from the rear side of the middle frame 10, they can grip the module gripping part 414 for easier operation. In comparison with the situation where the module gripping part 414 is not provided, this design enhances the safety of the display module 40 during the disassembly or assembly process.

Please refer to FIG. 16. The display support module 60 in the display device 8 is installed on the middle frame 10 and is located at the rear side of the middle frame 10. In some examples, the display support module 60 is installed on the side beams of the middle frame 10, while in other examples, the display support module 60 is installed on the middle beams 12 of the middle frame 10. In some examples, the display support module 60 supports both front-side and rear-side disassembly from the middle frame 10. Therefore, in some examples, the display support module 60 is fixed to the middle frame 10 using dual-operation-end fasteners. As the name suggests, the dual-operation-end fasteners have two operation ends, with one on the front side and one on the rear side of the middle frame 10, and both ends allow for the disassembly or assembly of the display support module 60. For instance, the dual-operation-end fastener can be a stud with recessed patterns on both ends or a double-headed bolt. In some examples, the dual-operation-end fastener used to secure the display support module 60 may be a double-headed pin shaft.

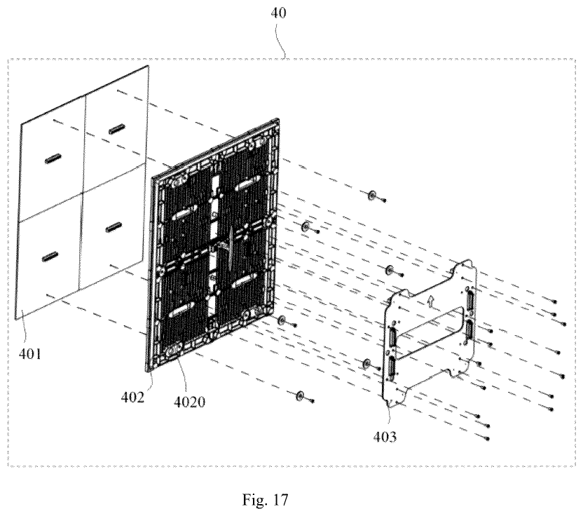

The following is a brief explanation of the remaining structure of the display module 40. Please refer to FIG. 17. The display module 40 includes a light board 401 and a back shell 402. The light board 401 is equipped with a chip array composed of multiple light-emitting chips, such as at least one type chosen from an LED array, a Micro-LED (micro light-emitting diode) array, a Mini-LED (mini light-emitting diode) array, and an OLED (organic light-emitting diode) array. The light board 401 is fixed to the front side of the back shell 402. When the display module 40 is installed onto the middle frame 10, the rear side of the back shell 402 faces the rear side of the middle frame 10.

It should be understood that the operation of the display module 40 requires a current driver and also needs to receive display control signals. Therefore, it must achieve both electrical and signal connections with the display support module 60, which is installed on the middle frame 10. As such, the display module 40 is equipped with a power interface corresponding to the power source as well as a signal interface corresponding to the signal adapter board. For the display module 40, these interfaces are considered external interfaces used to connect with the module interfaces on the middle frame 10. In some examples, the display module 40 also includes a splitter board 403, as shown in FIG. 17. The splitter board 403 is installed on the rear side of the back shell 402, which is the side opposite to the light board 401. The external interfaces of the display module 40 are located on the splitter board 403. In some examples, the splitter board 403 is equipped with only one set of external interfaces, which includes all the various interfaces necessary for the display module 40 to operate through external connections. In other examples of this embodiment, the splitter board 403 may include two sets of external interfaces. Please refer to FIG. 13. In the display module 40 shown in FIG. 13, the left and right sides of the splitter board 403 are both equipped with external interfaces 4030, specifically the left interface and right interface. This allows a single display module 40 to be installed on either the left or right side of the middle frame 10. With this design, the installer does not need to differentiate between the installation positions of the display module 40 during on-site installation, thereby enhancing the versatility of the display module 40 and improving the installation efficiency.

In the display device 8 provided in this embodiment, at least one of the power supply or the signal adapter board in the display support module 60 has dual backups. For example, in one case, a display device 8 may include both a primary power supply and at least one backup power supply as well as a primary signal adapter board and at least one backup signal adapter board. It is understood that in the event that there are backups of the display support modules 60 in the display device 8, if one of the display support modules 60 fails, the display device 8 can switch to the corresponding backup display support module 60 to continue operation, allowing the display device 8 to maintain functionality. In this situation, if the display device 8 is used in a conference hall, the installer can perform maintenance on the faulty display support module 60 from the rear side of the display device 8. This approach ensures that the maintenance does not disrupt the order or appearance of the venue, nor does it interrupt the ongoing meeting, thereby improving the overall user experience.

Please refer to FIG. 17 and FIG. 13. Since the front side of the light board 401 is equipped with numerous light-emitting chips and the rear side of the light board 401 is equipped with many driver chips, a significant amount of heat is generated when the light board 401 operates under the drive of current. To prevent the high-temperature environment from affecting the performance of both the light-emitting chips and the driver chips, heat dissipation needs to be considered. In some examples, a thermal conductive material is placed between the light board 401 and the back shell 402. This thermal material helps to conduct the heat generated on the light board 401 to the back shell 402, where the heat is dissipated. In other examples, the surface of the back shell 402, which faces away from the light board 401, is equipped with multiple heat-dissipating fins 4020. These fins 4020 increase the surface area of the back shell 402, thereby improving its heat dissipation efficiency.

To ensure the heat dissipation efficiency of the back shell 402, in this disclosure, the surface area of the splitter board 403, which is installed on the side of the back shell 402 facing away from the light board 401, is generally made smaller. This design prevents the splitter board 403 from obstructing the heat-dissipating fins 4020. Additionally, to ensure that the module gripping part 414 installed on the back shell 402 is exposed through the splitter board 403, the middle section of the splitter board 403 is hollowed out. This allows the module gripping part 414 to pass through the hollowed-out section and protrude from the splitter board 403.

The display device provided in this disclosure supports the disassembly and assembly of the display module from both the front and rear sides of the middle frame. The back cover supports disassembly and assembly from the rear side of the middle frame. Additionally, the display support module is fixed to the middle frame using dual-operation-end fasteners, which also allows the display support module to be disassembled and assembled from both the front and rear sides of the middle frame. This design facilitates maintenance of the display device components in different scenarios, improving the flexibility and efficiency of maintenance and reducing the maintenance workload. Furthermore, since the splitter board of the display module can be equipped with two sets of external interfaces, it enhances the versatility of the display module and improves installation efficiency. Additionally, by incorporating thermal conductive materials between the light board and the back shell and by installing heat-dissipating fins on the rear side of the back shell, these features enhance the display module's external heat dissipation capabilities, thereby improving the overall quality of the display module.

Please continue referring to FIG. 14. In the display device 8, the middle frame 10 primarily bears the load, while the display module 40 and the back cover 50 are mostly non-load-bearing. Therefore, when the display device 8 needs to be transported, the middle frame 10 typically serves as the main load-bearing component. In some examples, to facilitate transportation, a lifting handle is installed on the middle frame 10. FIGS. 15 and 16 show schematic diagrams of a partial structure of the middle frame 10, where the lifting handle 105 is positioned on the rear side of the middle frame 10 and is configured for manual gripping. In some examples, to help the installer keep the middle frame 10 as upright as possible while applying force to lift it, the lifting handle 105 is positioned toward the upper part of the rear side of the middle frame 10. In some examples, the lifting handle 105 is placed in an area on the rear side of the middle frame 10 that is covered by the back cover 50, ensuring the external aesthetics of the display device 8. However, when transporting the display device 8, the back cover 50 obstructs access to the lifting handle 105. In such cases, the back cover 50 can be removed before transporting the display device 8 and reinstalled on the middle frame 10 once it reaches its destination.

In some examples, a handle window is created on the back cover 50 of the display device 8, corresponding to the position of the lifting handle 105. This design allows the installer to access the lifting handle 105 on the middle frame 10 without having to remove the back cover 50. However, creating a handle window on the back cover 50 affects its structural integrity, potentially reducing its ability to protect the internal components of the display device 8 from moisture and dust.

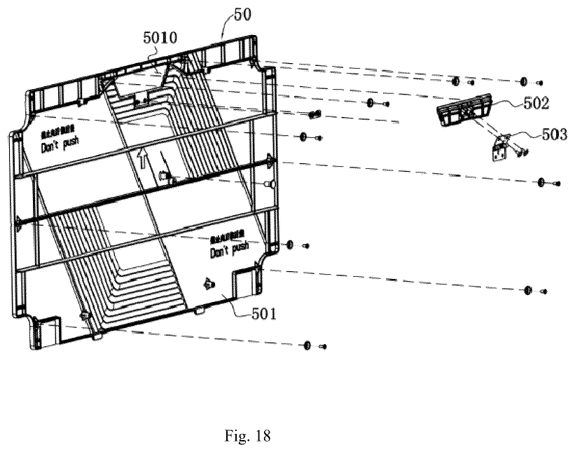

Please refer to FIG. 18 and FIG. 19. In other examples of this embodiment, the back cover 50 includes a back cover body 501 and a window shield 502. The back cover body 501 is provided with a handle window 5010, corresponding to the position of the lifting handle 105, allowing the installer to grip the lifting handle 105 through the handle window 5010. The handle window 5010 can be rectangular, trapezoidal, or invertedly trapezoidal. In FIG. 18 and FIG. 19, the handle window 5010 is shown as an inverted trapezoid. The window shield 502 is movably connected to the back cover body 501 through a connector. In the first state, the window shield 502 covers the handle window 5010, and in the second state, it exposes at least part of the handle window 5010. For a display device 8 with this type of back cover 50, when there is a need for transportation, the back cover 50 does not need to be removed. Instead, the window shield 502 can be shifted to the second state, allowing the installer's hand to reach through the handle window 5010 and grip the lifting handle 105 from the exterior of the display device 8. When there is no need for transportation, the window shield 502 can cover the handle window 5010 to protect the internal components of the display device 8.

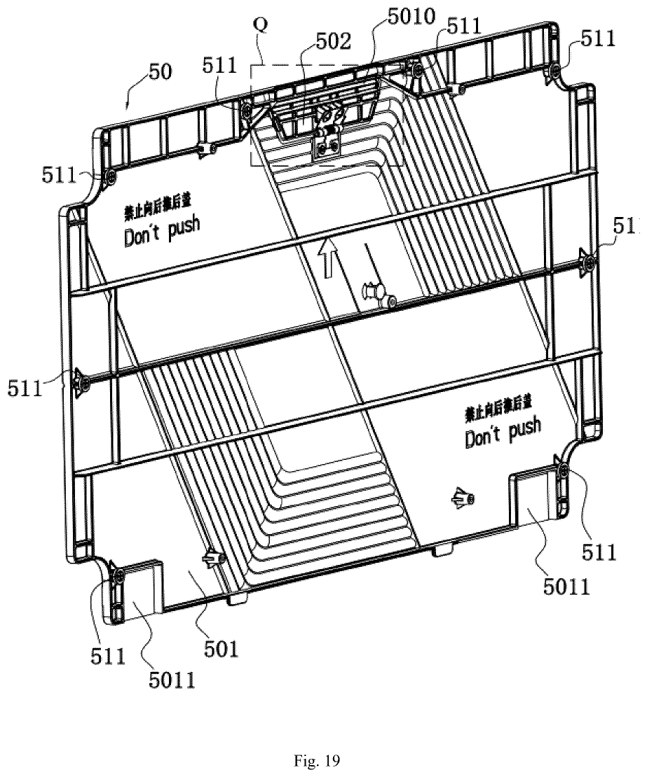

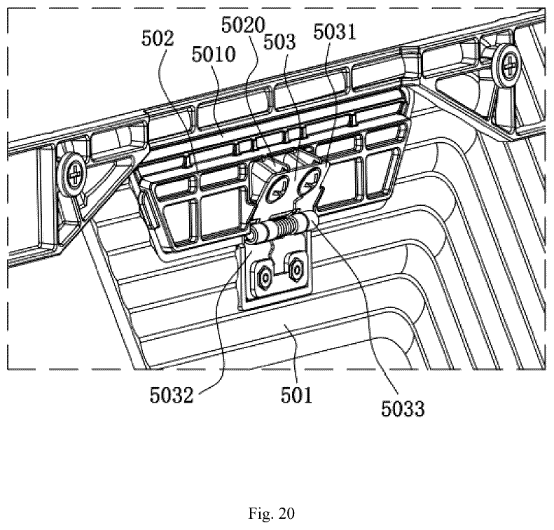

In some examples, the window shield 502 can be connected to the back cover body 501 through mechanisms such as clips or magnetic attachment. In this embodiment, the window shield 502 is connected to the back cover body 501 via a rotational connector. Please refer to FIG. 20, which is a partial enlarged view of area Q in FIG. 19. The rotational connector 503 is located on the side of the back cover 50 facing the display module 40; i.e., the rotational connector 503 is on the inner side of the back cover 50. The rotational connector 503 consists of a first connecting end 5031, a second connecting end 5032, and a rotating shaft 5033. Both the first connecting end 5031 and the second connecting end 5032 are connected to the rotating shaft 5033. The first connecting end 5031 and the second connecting end 5032 are fixedly connected to the window shield 502 and the back cover body 501, respectively. In this embodiment, the first connecting end 5031 can rotate in relation to the rotating shaft 5033, allowing the window shield 502, which is fixedly connected to the first connecting end 5031, to rotate around the rotating shaft 5033. After the back cover body 501 is installed on the rear side of the middle frame 10, if the installer needs to use the lifting handle 105, they can push the window shield 502 to rotate it in relation to the back cover body 501, exposing at least part of the handle window 5010 that it was covering. When there is no need to use the lifting handle 105, the window shield 502 can be returned to a position where it is flush with the back cover body 501, maintaining a uniform surface.

Undoubtedly, since one end of the rotational connector 503 needs to be connected to the window shield 502 and the other end needs to be connected to the back cover body 501, the rotating shaft 5033 of the rotational connector 503 should be positioned near the side of the handle window 5010, and the axis of the rotating shaft 5033 should follow the direction of that side. In some examples, the axis of the rotating shaft 5033 is parallel to the upper and lower edges of the handle window 5010. In other examples, the axis of the rotating shaft 5033 may also be parallel to the left and right edges of the handle window 5010. Typically, the upper and lower edges of the handle window 5010 are parallel to the upper and lower edges of the back cover 50, and the lifting handle 105 is also parallel to the upper and lower edges of the back cover 50. This arrangement allows the installer to easily insert their fingers, palm facing upward, inside the back cover 50 and grip the lifting handle smoothly, facilitating the operation of lifting the display device 8.

It should be understood that when the rotating shaft 5033 is positioned on the upper side of the handle window 5010 and aligned along the upper edge of the handle window 5010, the window shield 502 will naturally cover the handle window 5010 due to the effect of gravity when no external force is applied. In this situation, when the installer needs to use the handle window 5010, they only need to push the window shield 502 inward toward the middle frame 10, which will open the handle window 5010. Once the installer removes their hand and the external force is withdrawn, the window shield 502 will automatically return to its original position, covering the handle window 5010.

In some examples, the rotational connector 503 is a spring hinge, with one hinge serving as the first connecting end 5031 and the other as the second connecting end 5032. The spring hinge includes a return spring that allows the two hinges to automatically reset when no external force is applied. In this case, regardless of which side of the handle window 5010 on which the rotating shaft 5033 is located, the window shield 502 can automatically return to its original position. In some examples, the rotating shaft 5033 is located at and positioned along the lower edge of the handle window 5010. In this situation, when the installer pushes the window shield 502, it will rotate inward and downward.

Please refer to FIG. 20. In some examples of this embodiment, the window shield 502 includes a window shield body and a connecting wedge 5020 positioned on the side facing the middle frame 10. The window shield body is the main part of the window shield 502 and is generally sheet-shaped. The connecting wedge 5020 protrudes from the surface of the window shield body and is wedge-shaped. Its protrusion height increases as the distance from the rotating shaft 5033 increases. In other words, the further away from the rotating shaft 5033, the greater the protrusion height of the connecting wedge 5020 relative to the surface of the window shield 502. A threaded hole is provided on the connecting wedge 5020. The first connecting end 5031 of the rotational connector 503 is fixed to the connecting wedge 5020 by a screw. The screw passes through the connecting hole on the first connecting end 5031 and is screwed into the threaded hole on the connecting wedge 5020. In some examples, when the window shield 502 is in the first state, the plane of the window shield 502 coincides with the plane of the back cover body 501. It should be understood that “coincide” here refers to the plane of the back cover body 501 and the plane of the window shield 502 being approximately aligned but not perfectly aligned. Additionally, when the window shield 502 is covering the handle window 5010, the spring hinge is in a partially open state, meaning it is half-open. This configuration applies a certain preload to the window shield 502, preventing it from becoming loose and further ensuring the integrity of the window shield 502.

On the other hand, the protrusion height of the connecting wedge 5020 can provide sufficient space to accommodate the screw that locks the first connecting end 5031. In some examples, the threaded hole on the connecting wedge 5020 is a blind hole. The protrusion height of the connecting wedge 5020 is sufficient to allow the threaded hole to have enough thread length to engage with the screw and achieve secure locking. Since the threaded hole is a blind hole, the screw will not penetrate to the side of the window shield 502 that faces away from the middle frame 10. In other words, the screw connecting the window shield 502 will not be visible from the outside of the back cover 50, thereby enhancing the aesthetic appearance of the back cover 50.

In some examples, the thickness of the back cover 50 near the top corner regions of the middle frame 10 can be thinner than in other areas. Please refer to FIG. 19, where this thinner area of the back cover 50 is referred to as a “thin edge zone” 5011. In FIG. 19, two thin edge zones 5011 are shown on the back cover 50. However, those skilled in the art will understand that in other examples of this embodiment, the thin edge zones 5011 can be distributed in all areas of the back cover 50 that are near the top corners of the middle frame 10. In this case, four thin edge zones 5011 can be placed on a single back cover 50. Since the thin edge zones 5011 are thinner than other areas, they are more susceptible to being damaged by external forces. When the installer needs to create an opening in the back cover 50 for signal or power cables to pass through from the middle frame 10, they can directly remove the thin edge zones 5011 by cutting or other methods, thus forming an outlet hole in the back cover 50.

The display device 8 provided in this embodiment includes a lifting handle 105 on the middle frame 10 and a handle window 5010 on the back cover 50 that aligns with the lifting handle 105. This design allows the installer's hand to pass through the back cover 50 and grip the lifting handle 105 when the display device 8 needs to be transported. More importantly, a window shield 502 is installed on the handle window 5010. In the first state, the window shield 502 covers the handle window 5010, enhancing the integrity of the back cover 50, improving its aesthetics, and ensuring that the back cover 50 effectively protects the internal components of the display device 8. In the second state, the window shield 502 exposes at least part of the handle window 5010. The handle window 5010 on the back cover 50 also greatly facilitates the installation and removal of the back cover 50. Without the handle window 5010, installers would find it difficult to locate a suitable leverage point when removing the back cover 50, especially during disassembly, making the process more challenging. However, with the handle window 5010, installers can insert their fingers into the window to easily perform the disassembly and installation, thereby improving the ease of operation.

### Embodiment 2

For splicing display screens, which consist of at least two display modules, it is necessary to establish electrical connections between the middle frames of each display module to facilitate coordinated control. The conventional method is to place through-holes in the adjacent side walls of the middle frames and use flexible power cable connectors to connect the circuits of the display modules through these holes. However, the flexible power cable connectors lack a fixed position and tend to move around, making it difficult for installers to operate. The installers have to use both hands to handle the electrical interfaces of two middle frames in a cramped space, making the process inconvenient. Additionally, the wiring can become messy, and the power cable connectors can easily bump into internal circuits, potentially causing electrical failures. To address this issue, this disclosure further provides a splicing display screen in which a first electrical interface component and a second electrical interface component are placed between two adjacent middle frame bodies that are spliced together. The first electrical interface component includes a slidable first electrical interface, and the positions of the first and second electrical interfaces are fixed. The first and second electrical interfaces are connected and disconnected by the linear sliding motion of a movable part. This eliminates the need for installers to insert or remove cables in the narrow space on the side of the middle frame, and it prevents power cable connectors from bumping into internal circuits and causing electrical failures. The operation is simple and convenient, the wiring is neat and aesthetically pleasing, and the reliability of the interface connection is excellent. It should be understood that the middle frames, splicing plates, and other structures used in the splicing display screen of this embodiment can adopt the structure described in Embodiment 1 or other structures. In other words, the splicing display screen provided in this embodiment can be implemented independently of Embodiment 1. For ease of understanding, the following section provides an example description in conjunction with the accompanying diagrams.

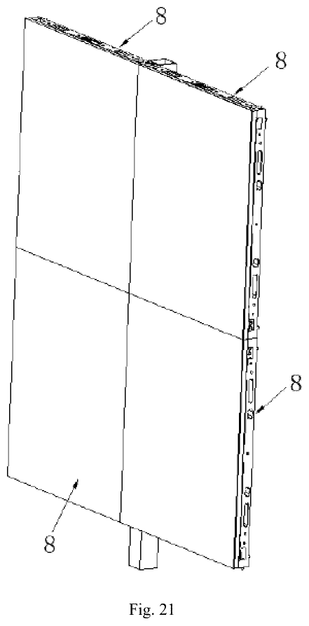

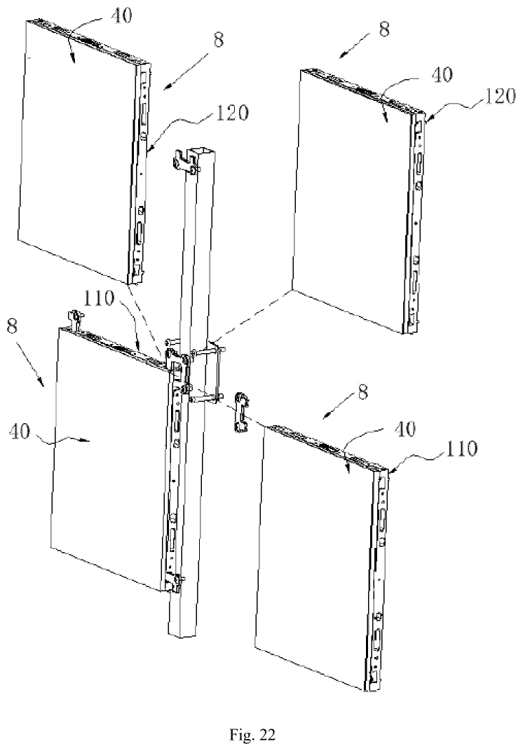

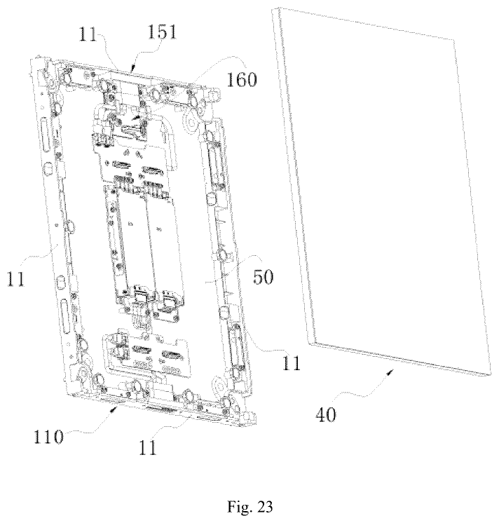

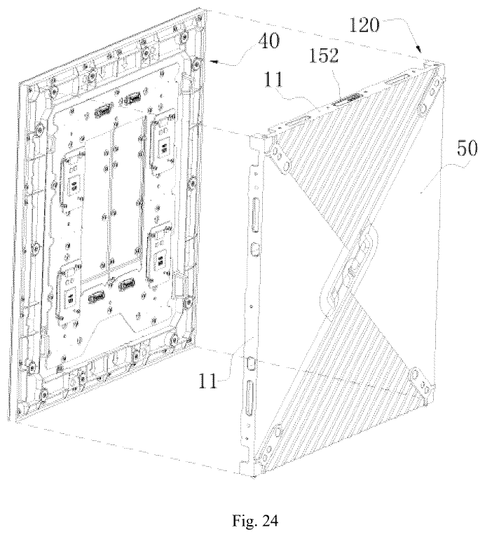

Referring to FIGS. 21 and 22, this embodiment provides a splicing display screen composed of four spliced display devices 8. In other examples, the user can determine the number of display devices 8 required based on the desired screen size, but at least two display devices 8 are needed to create a splicing screen. As shown in FIGS. 21 to 24, the splicing display screen provided in this embodiment includes at least two interconnected middle frames. In this example, the middle frames are represented by the first middle frame 110 and the second middle frame 120, which should be understood as relative terms. Each middle frame (the first middle frame 110 and the second middle frame 120) has a display module 40 mounted on the front side and a back cover 50 (also referred to as a back plate in this embodiment) mounted on the rear side. Each middle frame (the first middle frame 110 and the second middle frame 120) also includes a side beam 11 (also referred to as a side plate), and the side beam 11 can be fixedly connected to the side of the back cover 50.

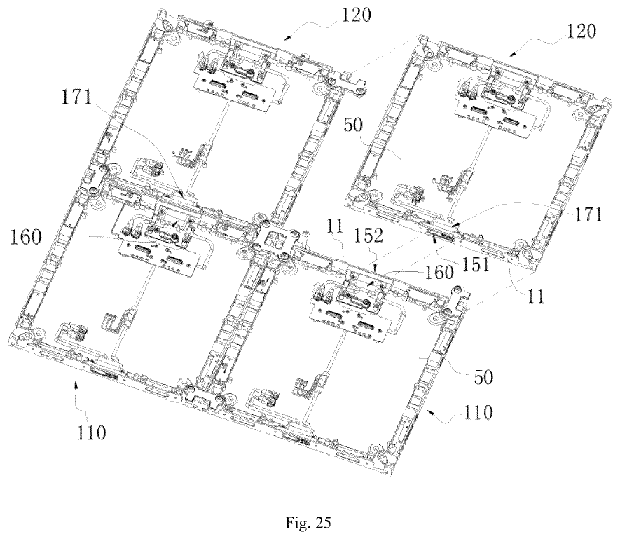

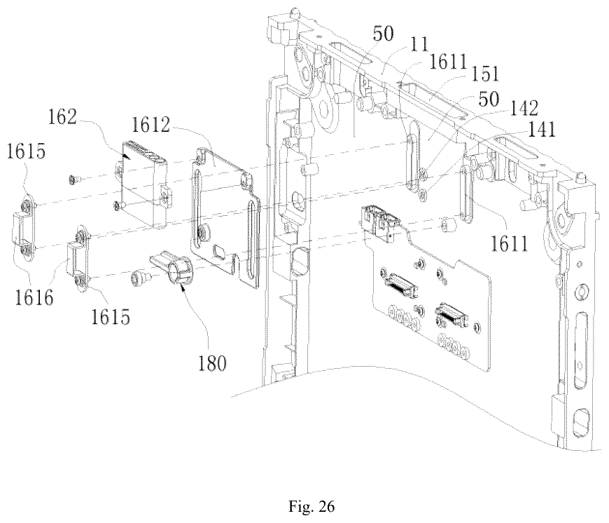

As shown in FIGS. 25 to 27, the adjacent side beams 11 of the first middle frame 110 and the second middle frame 120 are respectively equipped with corresponding first electrical through-hole 151 and second electrical through-hole 152. After the alignment and splicing of the first middle frame 110 and the second middle frame 120, the first electrical through-hole 151 and the second electrical through-hole 152 can be interconnected. The back cover 50 installed on the first middle frame 110 is equipped with a first electrical interface component 160, which includes a bracket 161 and a first electrical interface 162. The bracket 161 consists of a fixed part 1611 and a movable part 1612 that is movably connected to the fixed part 1611. The fixed part 1611 is fixedly connected to the back cover 50, and the movable part 1612 is limited to sliding in relation to the fixed part 1611 in the first direction. The movable part 1612 is also positioned on the rear side of the back cover 50. The first electrical interface 162 is connected to the movable part 1612 by a second fastener. The second middle frame 120 is equipped with a second electrical interface 171, which corresponds to the first electrical interface 162. The second electrical interface 171 is fixedly connected to the second middle frame 120 and exposed through the second electrical through-hole 152.

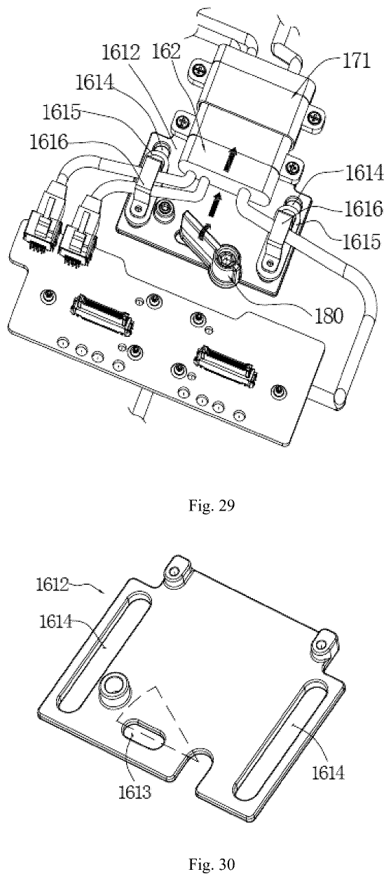

The first electrical interface 162 slides along the first direction through the movable part 1612 to connect with the second electrical interface 171 via the first electrical through-hole 151 or to disconnect from the second electrical interface 171 by sliding away. When two middle frames need to be connected or separated, the operator can directly or indirectly drive the movable part 1612 located on the rear side of the back cover 50. This allows the first electrical interface 162 to slide in the first direction toward the second electrical interface 171 (forward sliding, as shown by the arrow in FIG. 29) to connect with the second electrical interface 171 or slide in the opposite direction (backward sliding, opposite to the forward direction) to disconnect from the second electrical interface 171. The first electrical interface 162 and the second electrical interface 171 achieve connection and disconnection through the linear sliding motion of the movable part 1612. Installers do not need to plug or unplug cables in the narrow space on the side of the middle frame, avoiding the issue of power cable connectors bumping into internal circuits and causing electrical faults. This design makes the operation convenient, keeps the wiring neat and aesthetically pleasing, and ensures high reliability of the interface connection.

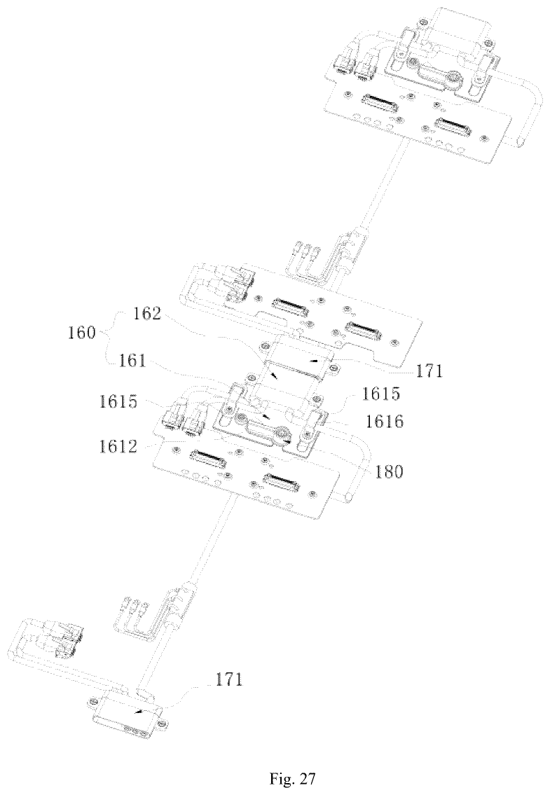

Refer to FIG. 27, which shows the state where the first electrical interface 162 is not connected to the second electrical interface 171 (i.e., the first electrical interface 162 is separated from the second electrical interface 171), and FIG. 29, which shows the state where the first electrical interface 162 is connected to the second electrical interface 171. The first electrical interface 162 extends into the second electrical interface 171 located in the second middle frame 120 (not shown in FIG. 29), allowing the circuit to be conducted. Additionally, it provides positioning and limiting functions between the middle frames.

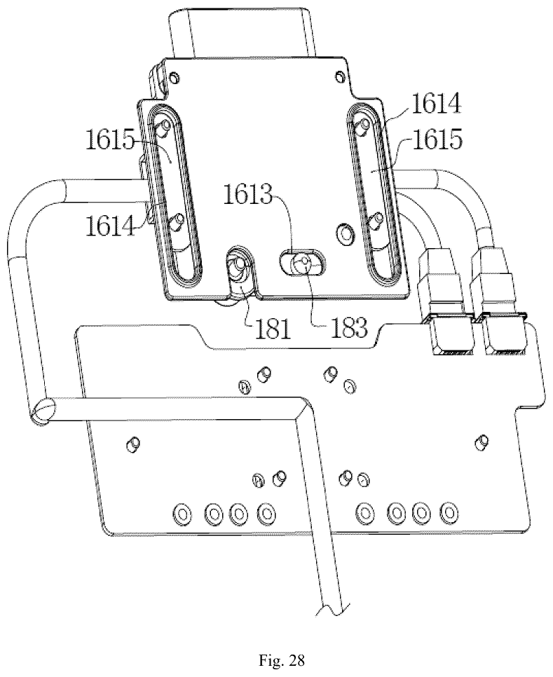

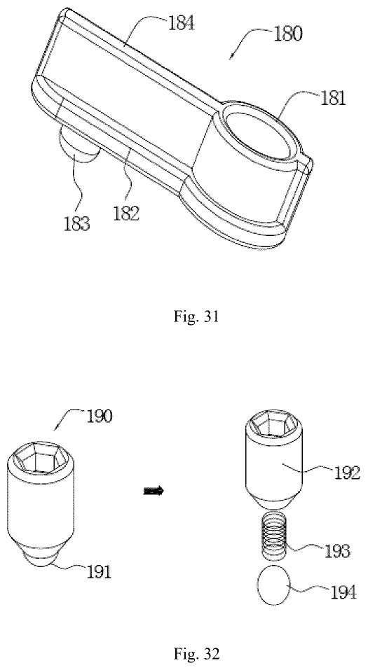

In some examples, as shown in FIGS. 28 to 31, the first middle frame 110 also includes an operating component 180. The operating component 180 consists of a rotating shaft 181, a connecting rod 182, and a push rod 183. The rotating shaft 181 is rotatably connected to the back cover 50, and the push rod 183 is connected to the movable part 1612. The connecting rod 182 connects the rotating shaft 181 and the push rod 183. The rotating shaft 181 has a through-hole for the installation of a second fastener, which can be an internal hex bolt or a similar element, allowing the rotating shaft 181 to be locked in place. This ensures that the first electrical interface 162 and the second electrical interface 171 maintain a stable and reliable connection. The rotating shaft 181 can rotate to drive the movable part 1612 to slide forward or backward along the first direction. The rotating shaft 181 is connected to the connecting rod 182, which provides a relatively long lever arm. This design makes the operation of the rotating shaft 181 more labor-efficient, allowing the operator to easily and reliably drive the movable part 1612 to slide forward or backward along the first direction. The operating component 180 can remain assembled on the first middle frame 110, or it can be used as a detachable tool accessory.

In some examples, as shown in FIGS. 28 to 31, the connecting rod 182 is equipped with a handle part 184. The handle part 184 is a plate protruding from the connecting rod 182 and extends along the direction of the connecting rod 182. The handle part 184 protrudes from the rear side of the back cover 50, allowing the operator to easily manipulate the connecting rod 182 by using the handle part 184, thereby rotating the entire rotating shaft 181. This design provides convenient operation.

In some examples, as shown in FIGS. 28 to 30, the movable part 1612 is equipped with a second limiting slot 1613. The push rod 183 is placed inside the second limiting slot 1613, which facilitates the application of pushing and pulling forces by the push rod 183 to the movable part 1612.

In some examples, as shown in FIGS. 28 to 30, the movable part 1612 is provided with a guide slot 1614, and at least part of the fixed part 1611 is located inside the guide slot 1614. The movement of the movable part 1612 along the first direction is constrained by the guide slot 1614, which defines the maximum travel distance of the movable part 1612. This prevents the first electrical interface 162 and the second electrical interface 171 from being pressed together too tightly, which could damage the interfaces. It also helps prevent excessive pulling on the related cables, ensuring the stability and reliability of the structure.

In this embodiment, the fixed part 1611 is a raised platform integrally formed with the back cover 50. The raised platform is entirely positioned inside the guide slot 1614, reducing assembly steps and providing a reliable structure.

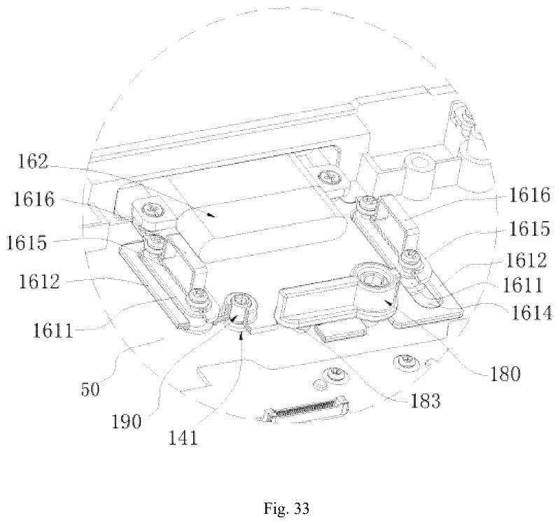

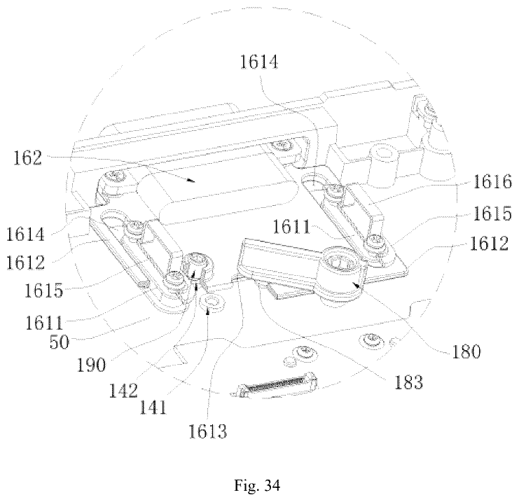

In some examples, the movable part 1612 is equipped with a positioning component 190. The positioning component 190 has an elastic protrusion 191 that connects to the back cover 50. The positioning component 190 has a first position (shown in FIG. 33) and a second position (shown in FIG. 34) along the first direction. The back cover 50 of the first middle frame 110 is provided with a first positioning hole 141 and a second positioning hole 142. The positioning component 190 fits into the first positioning hole 141 and the second positioning hole 142 in the first and second positions, respectively. As shown in FIGS. 27 and 33, when the positioning component 190 is in the first position and fits into the first positioning hole 141, the first electrical interface 162 is not connected to the second electrical interface 171. As shown in FIGS. 29 and 34, when the positioning component 190 is in the second position and fits into the second positioning hole 142, the first electrical interface 162 is connected to the second electrical interface 171.

In some examples, as shown in FIGS. 28 to 30. The top of the fixed part 1611 is equipped with an anti-detachment tab 1615, which is used to prevent the movable part 1612 from detaching from the fixed part 1611, ensuring the reliability of the structure. The anti-detachment tab 1615 is also equipped with a pressing plate 1616, which is used to secure cables in place to prevent misalignment, tangling, or accidental compression.

In some examples, the first middle frame 110 is equipped with a first circuit board electrically connected to the first electrical interface 162, and the second middle frame 120 is equipped with a second circuit board electrically connected to the second electrical interface 171. The first circuit board is connected to the display module 40 of the first middle frame 110, and the second circuit board is connected to the display module 40 of the second middle frame 120.

In some examples, the first middle frame 110 and the second middle frame 120 may be identical, both equipped with the first electrical interface component 160 and the second electrical interface component 170. The first and second electrical interface components 160 and 170 can be positioned at the top and bottom of the middle frame to facilitate splicing of multiple middle frames. Alternatively, the first and second electrical interface components 160 and 170 can also be positioned on the left and right sides of the middle frame.

Referring to FIG. 32, the positioning component 190 includes a hollow stud 192, a spring 193, and a steel ball 194 positioned inside the hollow stud 192. Part of the steel ball 194 is pushed out of the end of the hollow stud 192 by the spring 193, forming the elastic protrusion 191. The elastic protrusion 191 can extend into the first positioning hole 141 or the second positioning hole 142. This positioning structure, using the spring 193 and steel ball 194, allows the operator to determine whether the movable part 1612 has slid into position and prevents the movable part 1612 from sliding inadvertently, which could result in loose connections, failure, or unwanted noise. This design enhances structural reliability.

In the splicing display screen provided in this disclosure, when two middle frames need to be connected or separated, the operator can directly or indirectly drive the movable part 1612 located on the rear side of the back cover 50. This allows the first electrical interface 162 to slide along the first direction toward the second electrical interface 171 (forward sliding, as shown by the arrow in FIG. 29) to connect with the second electrical interface 171. Alternatively, the first electrical interface 162 can slide in the direction away from the second electrical interface 171 (reverse sliding, opposite to the forward sliding direction) to disconnect from the second electrical interface 171. The first electrical interface 162 and the second electrical interface 171 achieve connection and disconnection through the linear sliding motion of the movable part 1612. This eliminates the need for installers to plug or unplug cables in the narrow space on the side of the middle frame, preventing potential issues such as power cable connectors hitting internal circuits and causing electrical failures. The operation is convenient, the wiring is neat and aesthetically pleasing, and the interface connection is highly reliable.

### Embodiment 3

For splicing display screens, ensuring uniformity and completeness of the display requires very high installation precision during the splicing process. When the number of display units to be spliced is large, accumulated installation errors may result in significant discrepancies between the actual positions of certain display units and their intended positions, thereby affecting the installation outcome or even preventing the installation from being completed. Therefore, improving the installation tolerance while maintaining high installation precision is a problem that urgently needs to be addressed. To solve this issue, this embodiment provides a middle frame. It should be understood that the middle frame in this embodiment can be applied to, but not limited to, the splicing display screens described in the previous embodiments. It can also be applied to other splicing display screens, meaning that the splicing display screen provided in this embodiment can be implemented independently of the previous embodiments, and there are no restrictions placed on its use.

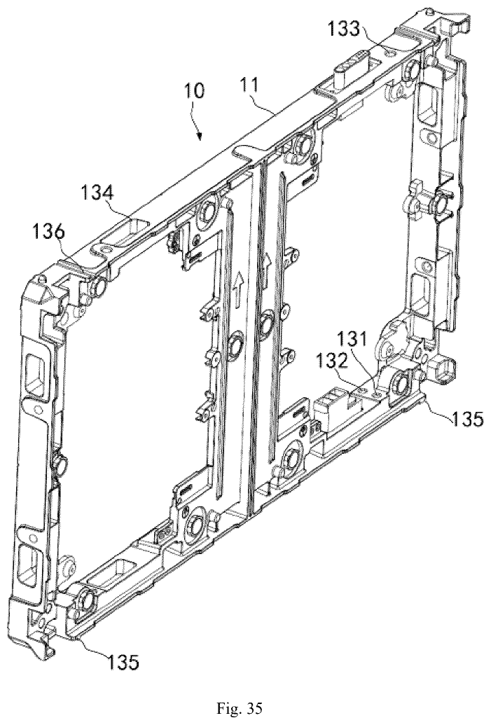

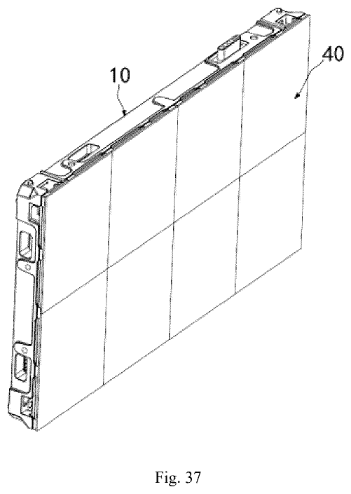

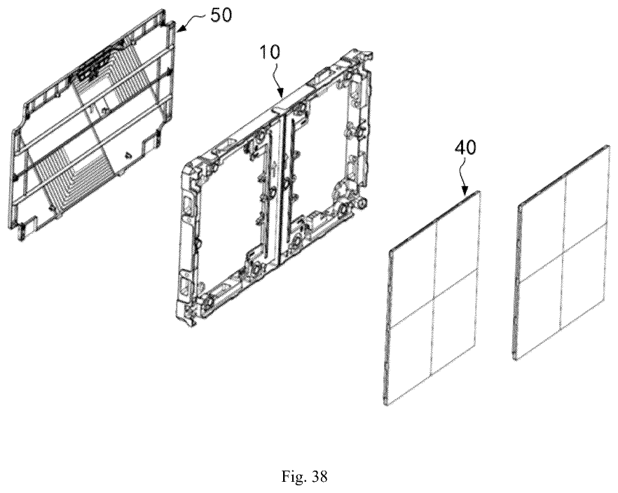

Please refer to FIGS. 37 and 38. The basic components of the display unit provided in this embodiment consist of three parts: the display module 40, the middle frame 10, and the back cover 50. Referring to FIG. 35, the middle frame 10 provided in this embodiment includes four side beams 11. The four side beams 11 are integrally formed to enclose the middle frame 10. Within the enclosed structure formed by the four side beams 11, a hollow area is created, which is part of the middle frame 10. For the entire display module, the outermost edge of the middle frame 10 is also the outermost edge of the display module 40. The outermost edge of the display module 40 is at most flush with the middle frame 10 and does not extend beyond it, ensuring that the middle frame 10 provides support and protection for the display module 40. The four side beams 11 of the middle frame 10 are categorized based on their position in the splicing structure: the upper beam located at the top, the lower beam located at the bottom, and the side beams located at both sides. To ensure that the middle frame 10 provides adequate support and protection for the display module 40, the middle frame 10 can be equipped with assembly components that correspond to the display module 40. The assembly methods include but are not limited to clips, magnetic attachments, threaded fasteners, adhesive bonding, etc. The specific assembly method is not limited in this embodiment.

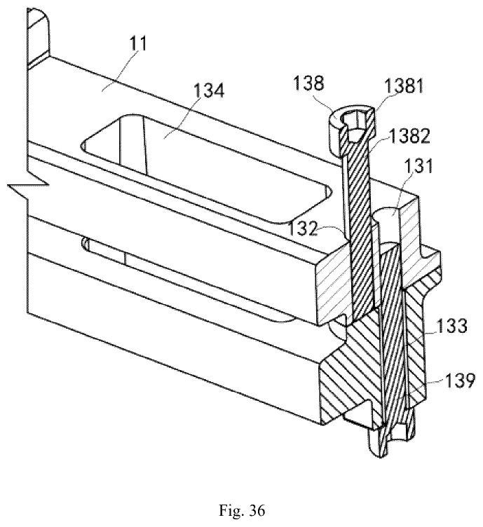

To connect adjacent display modules 40, multiple middle frames 10 are used for the connection. Please refer to FIG. 36, where the middle frame 10 includes multiple side beams 11, with at least two side beams 11 arranged to be opposite to each other. One of the side beams 11 is equipped with a set of first fixing holes 131 and a first adjustment hole 132 that passes through the side beam 11, while the other side beam 11 is equipped with at least one second fixing hole 133 corresponding to the first fixing hole 131. FIG. 37 shows a schematic diagram of the splicing of adjacent middle frames 10. During the assembly and connection of adjacent display modules 40, the corresponding side beams 11 are used for installation and connection. In the opposite side beams 11, one of the side beams 11 is equipped with a set of two holes: the first fixing hole 131 and the first adjustment hole 132. The first fixing hole 131 is used to align with the second fixing hole 133 on the adjacent display module 40, and the display modules are connected using a first fastener 139. The purpose of the first adjustment hole 132 is to fine-tune the position of the display module 40 using a first adjustment component 138. The first adjustment hole 132 includes a threaded hole, and the first adjustment component 138 includes a first bolt. The threaded hole is configured to allow the first bolt to be screwed in and extended, making contact with the side beam 11 of the adjacent middle frame 10 to adjust the gap between the adjacent middle frames 10. In this embodiment, the first bolt consists of a bolt head 1381 and a stud 1382 (i.e., the cylindrical threaded part of the first bolt). The length of the stud 1382 is greater than the depth of the first adjustment hole 132, allowing the first bolt to extend out of the first adjustment hole 132 during the connection process so that it can contact the side beam 11 of the adjacent middle frame 10. In this embodiment, both the first fastener 139 and the first adjustment component 138 can be bolts, each equipped with a bolt head. The ends of the bolt heads have recessed sections to accommodate operating tools (the cross-sections of these recesses can be hexagonal, slotted, Phillips, triangular, etc., and this embodiment does not limit the shape). These recessed sections allow for tightening or loosening using the corresponding tools.

The first adjustment hole 132 can also be configured as a through-hole, meaning it passes completely through the side beam 11 where it is located. Additionally, the first adjustment hole 132 is threaded, allowing the corresponding first bolt to be inserted into the first adjustment hole 132. By engaging the threads, the relative position between the first bolt and the first adjustment hole 132 can be adjusted, particularly the position where the first bolt extends out of the first adjustment hole 132. To achieve this, the length of the stud 1382 on the first bolt is greater than the depth of the first adjustment hole 132, allowing the first bolt to extend out of the first adjustment hole 132. If the first bolt extends out of the first adjustment hole 132, it can create a pushing effect, causing the first bolt to press against the middle frame 10 of the adjacent display module 40. This allows for fine adjustment of the display module 40's position. This fine adjustment can provide tolerance for installation errors in other display modules 40. If the installation position of another display module 40 deviates, the first adjustment hole 132 and the first bolt can work together to correct the position. The “stud” 1382 of the first bolt refers to the structure of the first bolt excluding the bolt head 1381. Typically, it includes a cylindrical structure with threads, which can either cover the entire cylindrical structure or only a portion of it. This embodiment does not limit the specific configuration.

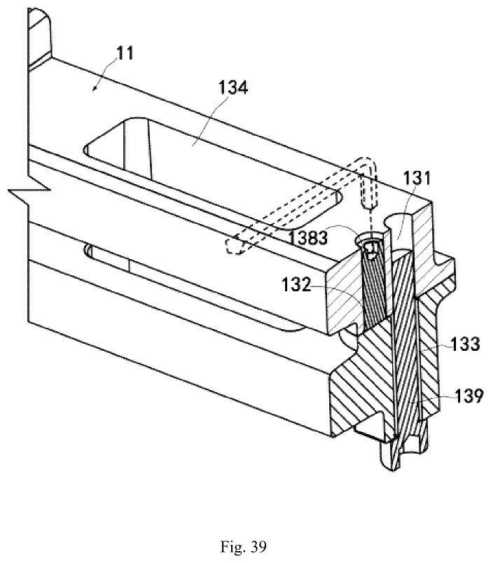

In some examples, the first bolt component can also be a stud, where the outer diameter of the stud's end is smaller than the outer diameter of its threaded section. Unlike a regular bolt, the stud does not have a head that is larger than the threaded section but instead has a more uniform overall size, with the outer diameter of the end being smaller than that of the threaded section. In this case, the length of the stud can be equal to or even less than the depth of the first adjustment hole 132, because the stud can sink deeper into the first adjustment hole 132, allowing the bottom of the stud to extend out of the first adjustment hole 132 and make contact with the side beam 11 of the adjacent middle frame 10. Please refer to FIG. 39, which shows a specific installation structure where the first bolt component includes a stud 1383. Since the outer diameter of the end of stud 1383 is smaller than the outer diameter of the threaded section, the end of stud 1383 can also extend into the first adjustment hole 132. Even if the length of stud 1383 is less than the depth of the first adjustment hole 132, this does not prevent stud 1383 from making contact with the side beam 11 of the adjacent middle frame 10. Additionally, in FIG. 39, the length of stud 1383 is shown to be less than the depth of the first adjustment hole 132, allowing stud 1383 to be fully recessed into the first adjustment hole 132 after assembly. This improves the overall appearance of the middle frame 10 and does not interfere with the installation of other components. During the assembly process, stud 1383 can be screwed in and out of the first adjustment hole 132 using a matching tool. FIG. 39 also shows that when the end of stud 1383 has an internal hexagonal recess, it can be rotated using a corresponding hex wrench.

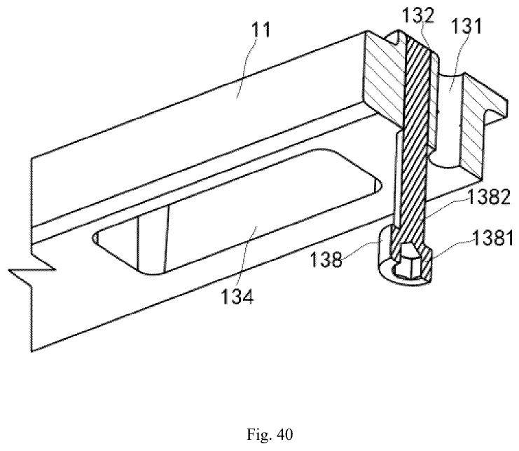

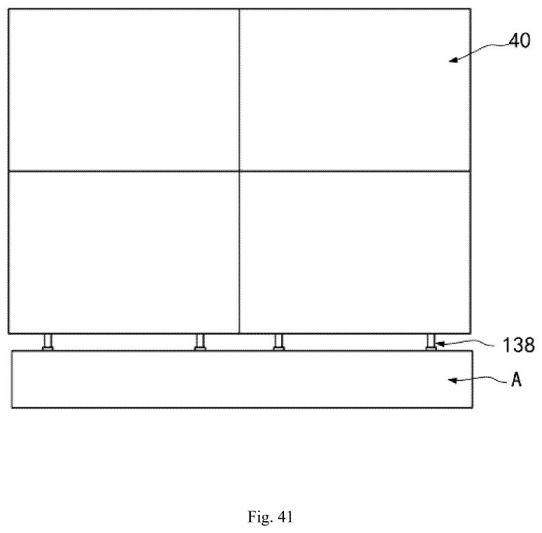

Additionally, large display screens formed by splicing multiple display units are often used in harsh environments such as outdoor settings, where uneven ground conditions are common. In such scenarios, a first adjustment hole 132 can be set on the lower side beam 11, and the first adjustment component 138 can be used to adjust the position of the display module 40 in relation to the ground, thereby improving the installation stability of the display screen. In other words, the first adjustment hole 132 is also configured to allow the first adjustment component 138 to pass through the side beam 11 (where the first adjustment hole 132 is located) of the middle frame 10 from the outside to the inside. Please refer to FIG. 40. During the splicing process of multiple middle frames 10, the lower side beam of the middle frame 10 at the very bottom does not need to align with the side beams 11 of other middle frames 10. Therefore, the corresponding first adjustment component 138 does not need to make contact with the side beam 11 of another middle frame 10. In this situation, to accommodate the installation environment at the bottom (i.e., the setup environment of the display device 8), the first adjustment component 138 can be inserted into the first adjustment hole 132 from the outside to the inside. This allows for easy external operation of the first adjustment component 138, enabling it to match the unevenness of the base, ground, support frame, or other components, thus ensuring that the entire display device 8 is balanced. Please refer to FIG. 41, where A represents the supporting surface, such as the base, ground, support frame, or other surfaces on which the display device 8 is placed.

In some examples, the first fastener 139 may specifically include a second bolt. The second bolt consists of an integrally formed bolt head and a stud. In the first fixing hole 131 and the second fixing hole 133, at least one is a through-hole, and at least the other is a threaded hole. The stud of the second bolt passes through the through-hole and engages with the threaded hole to secure the connection. Please refer to FIG. 36. The specific type of the second bolt can be a screw or bolt with an enlarged nut section. The external thread of the threaded rod engages with the internal thread of the threaded hole to achieve a secure connection, while the bolt head serves to limit the position of the second bolt. To accommodate the second bolt, at least one of the first fixing hole 131 or the second fixing hole 133 is a through-hole, and the other is a threaded hole. This allows the second bolt to pass through the through-hole and connect to the threaded hole, thereby securing the corresponding side beams 11 together. It is worth noting that for enhanced connection stability, a washer can also be used with the second threaded fastener.

In some examples, both the first fixing hole 131 and the second fixing hole 133 are threaded holes. When both the first fixing hole 131 and the second fixing hole 133 are threaded holes, the external threads of the second bolt can engage with the internal threads of both the first fixing hole 131 and the second fixing hole 133 simultaneously, thereby achieving a secure connection and effectively enhancing the stability of the connection. Of course, in this case, the thread direction of the first fixing hole 131 and the second fixing hole 133 must be consistent and match the thread direction of the second bolt.

In some examples, both the first fixing hole 131 and the second fixing hole 133 are through-holes, and the first fastener 139 includes a third bolt and a nut. The threads on the stud of the third bolt pass through the first fixing hole 131 and the second fixing hole 133 and are secured by the nut. In addition to allowing the third bolt to engage with the internal threads of the first fixing hole 131 and the second fixing hole 133, another option is to configure both the first fixing hole 131 and the second fixing hole 133 as through-holes. In this case, the third bolt and the nut are used to secure the connection between the adjacent side beams 11. In this scenario, both the first fixing hole 131 and the second fixing hole 133 can be smooth through-holes without internal threads. The third bolt passes directly through the first fixing hole 131 and the second fixing hole 133, and the connection is secured by locking a nut onto the end of the third bolt, thereby connecting the corresponding side beams 11 together.

In some examples, to ensure the reliability and symmetry of the installation, two sets of first fixing holes 131 are provided on the same side beam 11, positioned at the ends along the length of the side beam 11.

In some examples, the line connecting the center points of the same set of the first fixing hole 131 and the first adjustment hole 132 on the same side beam 11 is perpendicular to the length direction of the side beam 11. Please refer to FIGS. 35 and 36. The positions of the first fixing hole 131 and the first adjustment hole 132 relative to the length direction of the side beam 11 are located on the same coordinate along the side beam 11. This arrangement reduces the distance between the first fixing hole 131 and the first adjustment hole 132 to a certain extent, allowing for a smaller gap between the two. This helps minimize bending deformation during splicing.

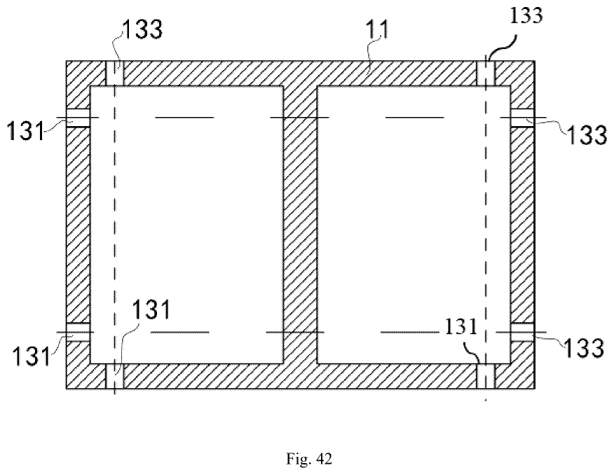

In some examples, the first fixing hole 131 and the second fixing hole 133 can be set on the upper and lower side beams 11, or on the left and right side beams 11, respectively. In other words, the first fixing hole 131 can be positioned on the lower side beam of the middle frame 10, with the second fixing hole 133 correspondingly positioned on the upper side beam of the middle frame 10, and/or the first fixing hole 131 can be placed on one of the side beams of the middle frame 10, with the second fixing hole 133 positioned on the opposite side beam of the middle frame 10. Please refer to FIG. 42. When placed on the upper and lower side beams 11, this allows for a connection between middle frames 10 positioned above and below each other. If placed on the left and right side beams 11, this enables connection between display modules 40 positioned to the left and right. Specifically, the splicing process of the display devices 8 generally starts from the bottom and moves upward. That is, the display modules 40 at the bottom are installed first, followed by the addition of display modules 40 above them, thereby connecting the adjacent upper and lower display modules 40. To facilitate easy connection, in the configuration where the first fixing hole 131 and the second fixing hole 133 are used, it is preferred that the first fixing hole 131 be placed on the lower side beam of the middle frame 10, while the second fixing hole 133 is correspondingly positioned on the upper side beam of the middle frame 10. In this structure, once the display module 40 at the bottom is installed, its second fixing hole 133 on the upper side beam remains open, and the display module 40 to be stacked above it will have its first fixing hole 131 on the lower side beam aligned with the second fixing hole 133. Then, the corresponding first fastener 139 is inserted through the first fixing hole 131, passing through it to engage with the second fixing hole 133, thereby securing the stacked display modules 40. If adjustment is required, the first adjustment component 138 can be screwed into the first adjustment hole 132 to engage the thread. The bottom of the first bolt (i.e., the first adjustment component 138) will extend out from the lower side beam of the upper display module 40 and push against the upper side beam of the lower display module 40, increasing the gap between the two display modules 40, allowing for position adjustment.

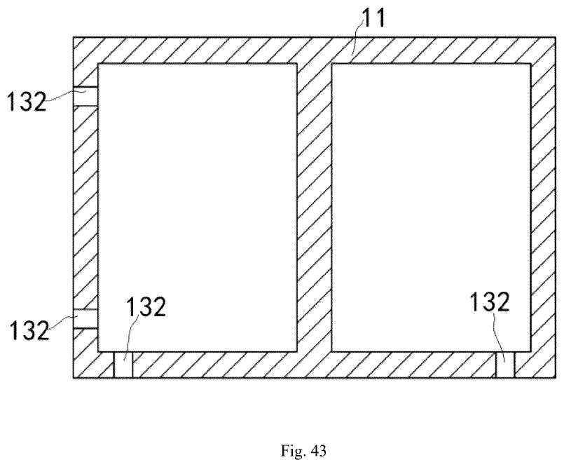

In some examples, depending on the placement of the first fixing hole 131, the corresponding first adjustment hole 132 is positioned accordingly. Specifically, the first adjustment hole 132 is set on the lower side beam 11 where the first fixing hole 131 is located, with the first adjustment component 138 passing through the first adjustment hole 132 from the inside of the middle frame 10 to the outside of the lower side beam 11. Alternatively, the first adjustment hole 132 can be set on the side beam 11 where the first fixing hole 131 is located, with the first adjustment component 138 passing through the first adjustment hole 132 from the inside of the middle frame 10 to the outside of the side beam 11. Please refer to FIG. 43 for details.

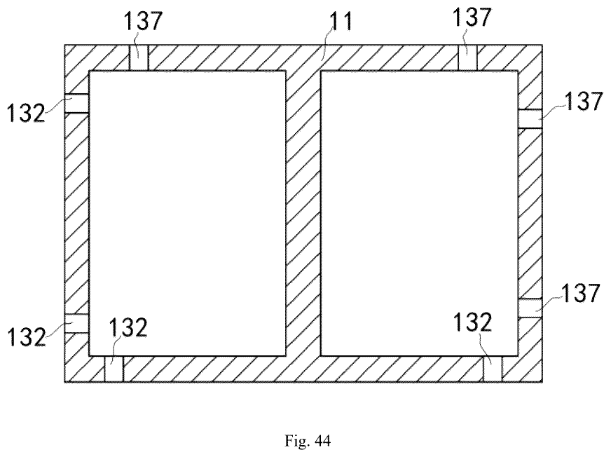

In some examples, to enhance adjustment flexibility, a second adjustment hole 137 may also be included. The second adjustment hole 137 is positioned on the side beam 11 where the second fixing hole 133 is located, and the second adjustment hole 137 is offset from the first adjustment hole 132. Please refer to FIG. 44. In addition to placing the first adjustment hole 132 on the side beam 11 where the first fixing hole 131 is located, the second adjustment hole 137 can also be placed on the side beam 11 where the second fixing hole 133 is located, allowing for adjustments through the second adjustment hole 137. To prevent interference between the first adjustment hole 132 and the second adjustment hole 137, the second adjustment hole 137 is offset from the first adjustment hole 132. When the second adjustment hole 137 is positioned on the upper side beam 11, a second adjustment component passes from below through the upper side beam 11. During adjustment, the second adjustment component passes through the upper side beam 11 and makes contact with the lower side beam 11 of the middle frame 10 positioned above. Alternatively, when the second adjustment hole 137 is positioned on the side beam 11, the second adjustment component passes from the inside to the outside through the side beam 11, and during adjustment, the second adjustment component passes through the side beam 11 and makes contact with the side beam 11 of the adjacent middle frame 10.

The middle frame 10 provided in this embodiment enables the splicing installation between two display modules 40 by setting the first fixing hole 131 and the second fixing hole 133 on the side beam 11 of the middle frame 10. Furthermore, the relative position adjustment between the display modules 40 is achieved through the first adjustment hole 132 and the first adjustment component 138, thereby improving the installation tolerance of the display modules 40 and ensuring the display quality of the large splicing display screen.

In some examples, at least one side beam 11 is provided with a wiring hole 134. The wiring hole 134 allows the hollowed-out area enclosed by the side beam 11 to connect with the external environment, enabling wiring to pass through while maintaining the integrity of the display module 40. The wiring hole 134 can be positioned on any side beam 11 and may be set on one or more side beams 11. Additionally, one or more wiring holes 134 may be positioned on the same side beam 11. Please refer to FIG. 35.

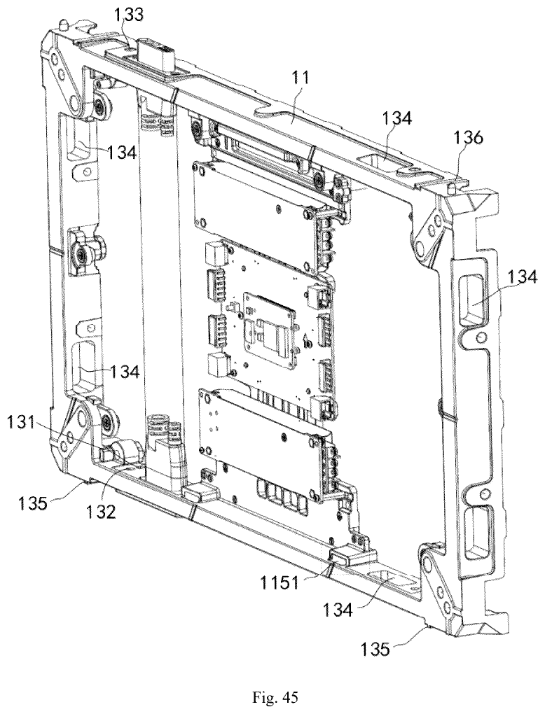

Please continue referring to FIG. 45. In some examples, at least one side beam 11 can be equipped with an anti-collision protrusion 135, which extends outward from the outer surface of the side beam 11. At least one side beam 11 can also be equipped with an anti-collision groove 136, which is recessed inward from the outer surface of the side beam 11 and corresponds to the anti-collision protrusion 135 on the adjacent display module 40's side beam 11. Corresponding to the placement of the anti-collision protrusion 135, an anti-collision groove 136 can also be set up to match with the anti-collision protrusion 135 on the side beam 11 of the other display modules 40. Additionally, the anti-collision protrusion 135 and the anti-collision groove 136 can be placed on the same side beam 11, and their corresponding counterparts on other display modules 40 can also be placed on the same side beam 11, further enhancing the engagement stability and improving the connection stability between display modules 40, thereby ensuring the structural reliability of the spliced display unit.

The present embodiment provides a splicing display screen, which includes at least two sets of display units. Among display units, adjacent display units are fixedly connected through a first fixing hole and a second fixing hole on adjacent side beams, in conjunction with a first fastener. This design allows for the relative position adjustment between the display unit groups, thereby improving the installation tolerance of the display units, ensuring the display effect of the splicing display screen.

### Embodiment 4

In the application of display modules, flat light fixtures, and other display or lighting fields, light boards are commonly used. To support and fix the light board, rigid components such as support members are usually required to secure the light board, ensuring its flatness and enhancing its strength after assembly. In existing technology, the common practice is to weld several internally threaded screw posts to the mounting surface of the light board, and then use externally threaded screws to attach the support member to the light board, thus achieving a fixed connection between the support member and the light board. The biggest drawback of this connection method is that welding can easily cause local heat deformation of the light board, and once the solder is fixed, it is difficult to correct if the position is wrong. This greatly increases the precision requirements for processing the light board, resulting in high manufacturing costs for the light board assembly and low production efficiency. To address this issue, this embodiment provides a light board component and its assembly method, which significantly reduces the error rate while ensuring reliable assembly and also improves production efficiency. The light board component provided in this embodiment can be applied to the display modules shown in the above embodiments, as well as other display modules, flat light fixtures, etc. In other words, the light board component provided in this embodiment can be implemented independently of the above embodiments, and is not limited to them.

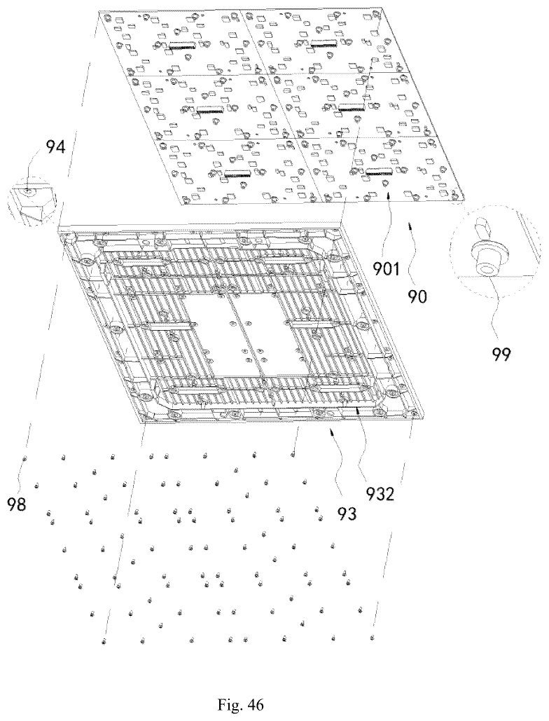

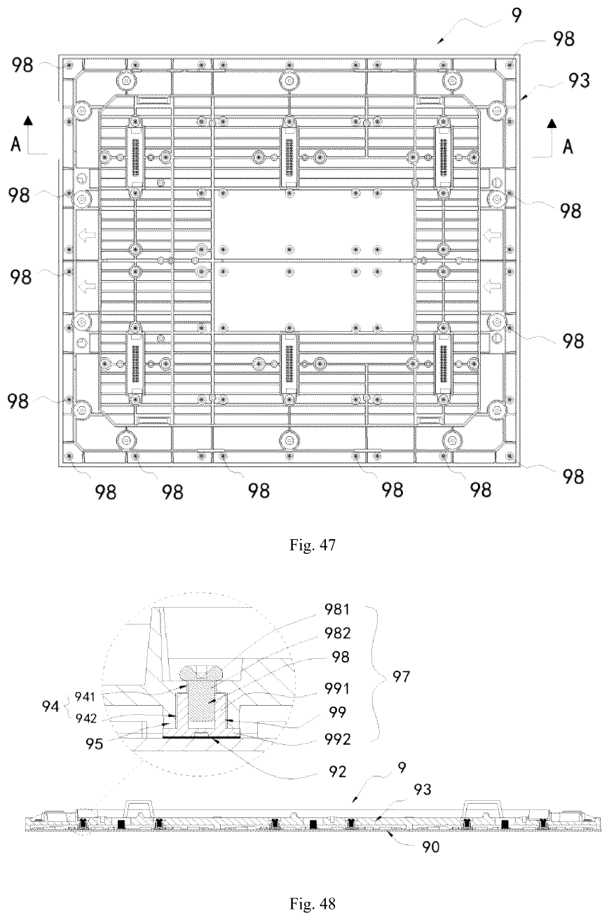

Referring to FIGS. 46 to 49 and FIG. 50a, this embodiment provides a light board component 9, which includes a supporting member 93, a light board 90, and a connecting element 97. The connecting element 97 comprises a first connector 98 and a second connector 99. The supporting member 93 has a first surface 931 for connecting with the light board 90 and a second surface 932 opposite to the first surface 931. The light board 90 has a third surface 901 for connecting with the supporting member 93 and a fourth surface 902 opposite to the third surface 901. A mounting hole 94 is set on the supporting member 93, penetrating both the first surface 931 and the second surface 932. The first connector 98 is tightly coupled with the second connector 99 via the mounting hole 94, forming a stable but detachable connection. This connection can be disassembled using tools or manually while ensuring no loosening at the connection point. The second connector 99 is installed on the first surface 931. Adhesive 92 is applied on the third surface 901 at the position corresponding to the second connector 99. The adhesive 92 bonds the second connector 99 to the third surface 901 of the light board 90, while the supporting member 93 does not come into contact with the adhesive 92. This design prevents difficulties in disassembling the light board component 9 during the assembly process.

The light board component 9 provided in this embodiment uses adhesive 92 to connect the second connector 99. This avoids the issue of localized heat deformation of the light board caused by the welding process used in existing technologies. In comparison with solder, adhesive 92 is easier to repair. Even if there is an error in the adhesive placement of a second connector 99, it can be easily corrected.

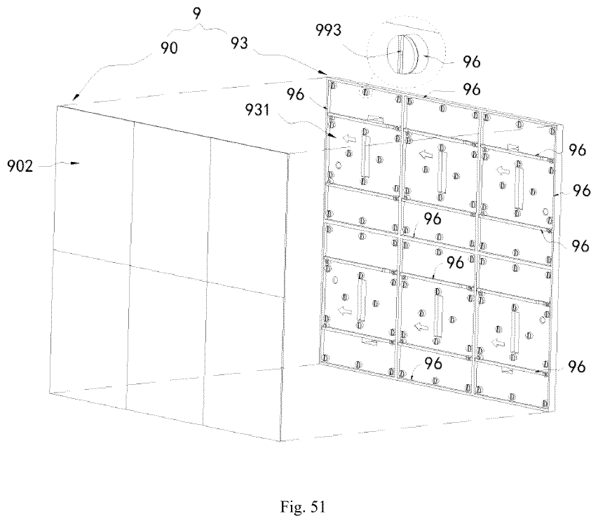

The light board component 9 in this embodiment, depending on the type, may include either a display-type light board or a lighting-type light board. The display-type light board may specifically include a direct-lit backlight light board or an LED direct display light board. The light source set on the light board 90 includes multiple light-emitting chips arranged in an array on the light-emitting surface 902, as shown in FIG. 51. The light-emitting chips are typically arranged at equal intervals both horizontally and vertically, meaning the spacing between two adjacent light-emitting chips in the horizontal direction is equal, and the spacing between two adjacent light-emitting chips in the vertical direction is also equal. Depending on the manufacturing process, the die bonding of the light-emitting chips on the light board 90 may be completed either before or after the assembly of the light board 90 with the supporting member 93.

The supporting member 93 (which can also be referred to as the base shell) is made of a rigid material, possessing a relatively stable form that is resistant to both elastic and non-elastic deformation. For example, it can be made of metal, including alloys, or hard plastic. The shape of the supporting member 93 is typically an integrated structure that matches the dimensions of the light board 90. For instance, the supporting member 93 could be a one-piece supporting plate similar in size to the light board 90, or it could be a shell structure with a contour that is designed to fit the display device 8 that the light board component 9 is to be assembled with. Additionally, considering factors such as weight reduction or cost, the supporting member 93 can also be designed as a frame structure composed of several reinforcing ribs, as long as it meets the specific application requirements of the light board component 9. The fixed connection between the light board 90 and the supporting member 93 is achieved through the assembly method of the light board component 9 in this embodiment.

The structure of the light board 90 in this embodiment is mainly composed of a circuit board or various types of substrates, with multiple light-emitting chips mounted on it. The purpose of the mounting holes 94 is to provide a basis for the initial connection between the connecting element 97 and the supporting member 93. These mounting holes 94 are arranged in a regular array on the supporting member 93, meaning they are uniformly distributed on the supporting member 93. Typically, the number of connecting elements 97 matches the number of mounting holes 94. However, if the structural strength allows, fewer connecting elements 97 can be used than the number of mounting holes 94, meaning not all the mounting holes 94 on the supporting member 93 need to be used for fixed connections, providing a certain degree of flexibility in design.

The connection between the connecting element 97 and the supporting member 93 is detachable. To achieve this detachable connection, the connecting element 97 consists of two components: the first connector 98 and the second connector 99. The first connector 98 and the second connector 99 can pass through the through-hole to connect, forming a detachable fixed connection among the first connector 98, the second connector 99, and the supporting member 93. Based on this detachable connection design, once the connection is disassembled, the supporting member 93 and the light board 90 can be separated after assembly without damaging the adhesive structure between the connecting element 97 and the light board 90. In this embodiment, the first connector 98 and the second connector 99 achieve the detachable connection using the mounting hole 94 on the supporting member 93. Specific forms of connection include, but are not limited to, snap-fit connections, mortise and tenon joints, threaded connections, and so on.

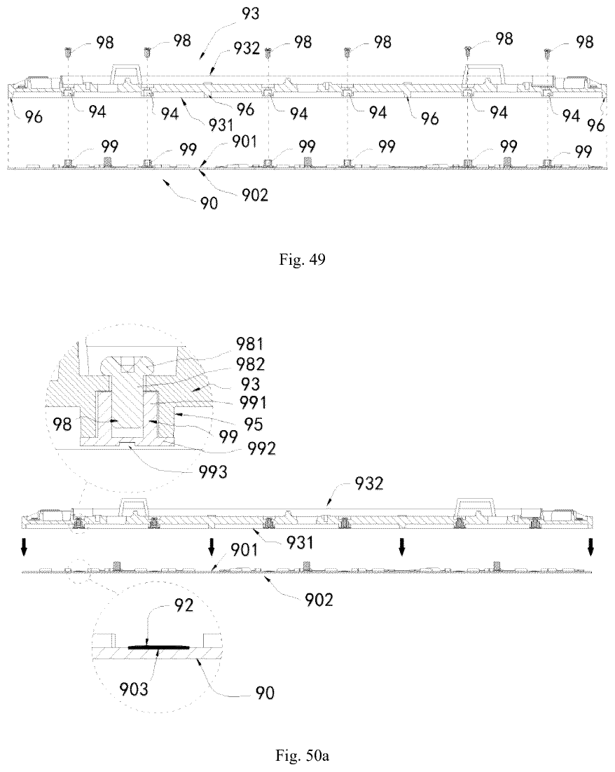

In some alternative embodiments, referring to FIGS. 48 and 49, using a threaded connection as an example, the first connector 98 includes a second threaded part with external threads, and the second connector 99 includes a nut hole with internal threads. The second threaded part and the nut hole achieve a detachable connection through the mating of the internal and external threads. The second threaded part is located on the upper surface side of the supporting member 93, and its threaded section with external threads can pass through the mounting hole 94 on the supporting member 93. The nut hole is located on the lower surface side of the supporting member 93, where the external threads of the second threaded part can extend into the internal threads of the nut hole, forming a detachable fixed connection between the second threaded part and the nut hole through the thread mating. The bottom of the nut hole is bonded to the light board 90 with adhesive 92. Once the assembly of the light board 90 and the supporting member 93 is completed, the light board 90 can be separated from the supporting member 93 by disassembling the thread mating between the second threaded part and the nut hole. Refer to FIG. 49 for a schematic diagram of the disassembly of the light board component 9 after assembly.

In some examples, referring to FIG. 48, to enhance the bonding reliability between the nut hole and the light board 90, the nut hole may specifically include an integrally formed screw hole part 991 and a base 992. The base 992 is positioned closer to the light board 90 in comparison with the screw hole part 991, and the base 992 seals the bottom of the nut hole, preventing the adhesive 92 from coming into contact with the second threaded part. Additionally, the bottom surface area of the base 992 is larger than that of the screw hole part 991, which increases the contact area between the base 992 and the adhesive 92, thus enhancing the bonding strength between the nut hole and the third surface 901 of the light board 90. In this embodiment, the screw hole part 991 is cylindrical, and the base 992 is circular, with the outer diameter of the base 992 being larger than that of the screw hole part 991. In other embodiments, the base 992 could also be square, oval, or in other shapes.

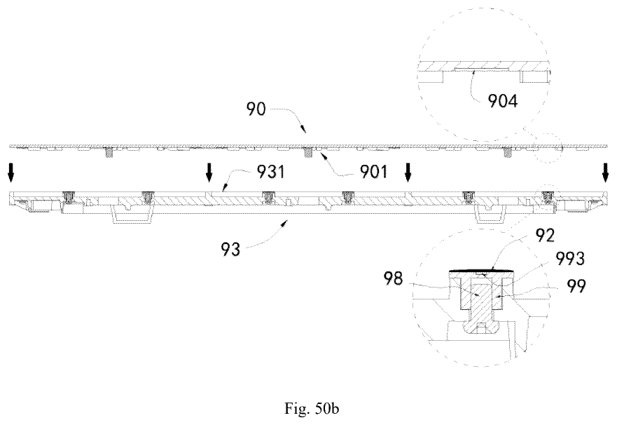

Referring to FIG. 50a, in this embodiment, to facilitate the assembly of the light board component 9, the connecting elements 97 can be pre-installed on the supporting member 93. To aid in fixing the connecting elements 97 to the supporting member 93, part of the connection between the second connector 99 (a nut hole in this embodiment) and the first connector 98 (a second threaded part in this embodiment) is embedded in the mounting hole 94. Specifically, the part of the mounting hole 94 facing the first connector 98 can accommodate part of the first connector 98, while the part of the mounting hole 94 facing the second connector 99 can house part of the second connector 99. This allows the mounting hole 94 to limit the position of both the first connector 98 and the second connector 99, making it easier to pre-align the second connector 99 during installation onto the supporting member 93, facilitating its connection with the first connector 98. In this embodiment, the first connector 98 is the second threaded part, which has a bolt head 981 and a screw rod part 982. The diameter of the bolt head 981 is larger than that of the screw rod part 982. The second connector 99 is a nut hole, and the mounting hole 94 is a stepped hole. The first diameter 941 of the mounting hole 94, which faces the second threaded part, is larger than the diameter of the screw rod part 982 but smaller than the diameter of the bolt head 981. The second diameter 942 of the mounting hole 94, which faces the nut hole, is larger than the outer diameter of the nut hole. During installation, part of the nut hole can be embedded in the mounting hole 94 before connecting the second threaded part with the nut hole. This design simplifies the installation of the second threaded part and the nut hole, improving installation efficiency. The edge of the mounting hole 94 can feature a first protrusion 95 extending towards the light board 90. The first protrusion 95 can extend the length of the mounting hole 94 and reduce the material usage of the supporting member 93, thereby reducing costs. In this embodiment, the first protrusion 95 can press against the base 992 of the nut hole, with the base 992 having a larger surface area than the end of the first protrusion 95 does. This arrangement isolates the first protrusion 95 from the adhesive 92, preventing the first protrusion 95 from coming into contact with the adhesive 92. Once the connecting elements 97 are fixed to the supporting member 93, the supporting member 93 equipped with the connecting elements 97 is obtained. The relative positions of the connecting elements 97 on the supporting member 93 are fixed, ensuring that there are no mismatches between the positions of individual connectors (either the first connector 98 or the second connector 99). Next, the light board 90 is placed horizontally with the third surface 901 (the installation surface) facing upward. The supporting member 93, equipped with the connecting elements 97, is placed above the light board 90.

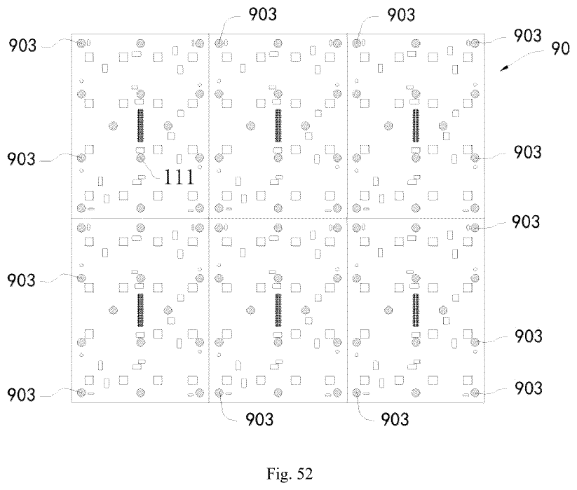

Several connection regions 903 corresponding to the positions of the second connecting components 99 are arranged on the installation surface. Adhesive 92 is pre-applied to the connection regions 903 to prepare for bonding the light panel 90 to the supporting component. Refer to FIG. 52, which shows a schematic diagram of the connection regions 903 on the installation surface of the light panel 90 (i.e., the third surface 901). The adhesive 92 is applied on the connection regions 903, where the locations of the connection regions 903 correspond to the positions of the second connecting components 99 on the supporting component 93. It should be noted that the correspondence between the positions of the connection regions 903 and the second connecting components 99 does not imply a perfect match. In practice, as long as the adhesive 92 ensures proper bonding between the second connecting components 99 and the third surface 901, and the bonding achieves the required strength, a certain degree of misalignment between the second connecting components 99 and the connection regions 903 is acceptable. The third surface 901 is the relevant surface on the light panel 90 that connects to the supporting component 93. It is typically opposite to the light-emitting surface of the light panel 90 (in this embodiment, the fourth surface 902, as shown in FIG. 51). The light-emitting surface refers to the surface on which the light-emitting chips are installed. After the light panel 90 is manufactured, its light-emitting surface is very flat and can be placed level with its surface facing downward.

The second connector 99 is then aligned with the adhesive 92, and the third surface 901 of the light board 90 is pressed against the first surface 931 of the supporting member 93, so that the second connector 99 bonds with the adhesive 92 while the supporting member 93 does not come into contact with the adhesive 92. Each second connector 99 is bonded to the connection area 903 through the adhesive 92. After the adhesive 92 cures, the desired light board assembly can be formed. Since the connection between the supporting member 93 and the connecting elements 97 is detachable, once the adhesive 92 cures, the light board 90 and the supporting member 93 can also be separated, allowing the supporting member 93 to be detached from the light board 90.

In this embodiment, during the pressing process, in order to leave a certain gap between the second connector 99 and the light board 90 to accommodate the adhesive 92, the supporting member 93 is provided with a second protrusion 96 facing the light board 90. The second protrusion 96 is the part of the supporting member 93 closest to the light board 90, and the distance between the second protrusion 96 and the light board 90 is greater than the distance between the second connector 99 and the light board 90. In this embodiment, the second protrusion 96 is in contact with the light board 90. In other embodiments, a spacer or other components may be placed between the second protrusion 96 and the light board 90. In this embodiment, the second protrusion 96 is arranged in strips, with multiple strips located at the edges and middle portions of the supporting member 93. This ensures that the force exerted by the first protrusion 95 on the light board 90 is relatively uniform. Additionally, the second protrusion 96 encloses the edges of the light board 90, providing dust protection for the edges of the light board 90. In one embodiment, the second protrusion 96 may also be columnar, such as cylindrical or prismatic, and distributed across the first surface 931 of the supporting member 93, leaving gaps between the second protrusions 96 for airflow. This creates more space between the supporting member 93 and the light board 90, facilitating heat dissipation from the light board 90. Since the second protrusion 96 is the part closest to the light board 90, it serves as a support point when pressing the light board 90 and the supporting member 93 together, preventing the second connector 99 from excessively compressing the adhesive 92. This ensures that the adhesive 92 maintains a certain thickness, thereby guaranteeing the bonding strength between the adhesive 92, the light board 90, and the second connector 99 while also reducing the amount of adhesive 92 that spills around the second connector 99. Because the adhesive 92 has some accommodation space and good plasticity, even if the bottom of the second connector 99 or the connection area is uneven, it will not affect the accuracy of the connection between the second connector 99 and the first connector 98. As long as the position and orientation of the first connector 98 and the second connector 99 are correctly pre-aligned, the adhesive 92, after curing, will maintain the connection accuracy between the first connector 98 and the second connector 99. Thus, the plasticity of the adhesive 92 reduces the error rate during the bonding process.

In another embodiment, as shown in FIG. 50b, the third surface 901 (installation surface) of the light board 90 can also be placed facing downward, with the supporting member 93, equipped with the connecting elements 97, positioned below the light board 90. The first surface 931 of the supporting member 93 is placed horizontally, and adhesive 92 is pre-applied to the bottom of the second connector 99. Afterward, the light board 90 is pressed together with the supporting member 93. Once the adhesive 92 cures, the light board component 9 can be obtained. The purpose of applying the adhesive 92 is to bond the light board 90 to the supporting member 93. To maintain the flatness of the light board 90, the adhesive 92 used in this embodiment has a certain thickness. In this structure, the thickness of the adhesive 92 allows for bonding between the second connector 99 and the installation surface 901, regardless of the varying orientations of the second connectors 99, without affecting the flatness of the light board 90. Specifically, the thickness of the adhesive 92 can be set to be greater than or equal to a first predetermined threshold, ensuring that during assembly, the second connectors 99 on the supporting member 93 make sufficient contact with the adhesive 92. In this scenario, even if the second connectors 99 are tilted or misaligned with the corresponding predetermined installation areas, they can still bond properly with the adhesive 92, and after bonding, the relative positions of all the second connectors 99 will be fixed.

In some examples, to prevent excessive application of adhesive 92 and subsequent overflow, the thickness of the adhesive 92 applied to the preset connection areas 903 on the third surface 901 can be set to be less than or equal to a second predetermined threshold. The second predetermined threshold is larger than the first predetermined threshold. Setting an upper limit for the thickness of the adhesive 92 helps to avoid applying too much adhesive 92, which could cause significant overflow from the preset connection areas 903 during bonding, potentially affecting the functionality of other components on the light board 90. In addition to setting an upper limit for the thickness of the adhesive 92, to further reduce the possibility of overflow, a first adhesive accommodating groove 904 can be provided in the connection area 903 (see FIG. 50b). This means that recesses are created at the bottom of the connection area 903 to hold the adhesive 92 and limit its flow. The first adhesive accommodating groove 904 allows the adhesive 92 to maintain a certain thickness, enhancing the bonding strength between the adhesive 92, the light board 90, and the second connector 99. Additionally, to reduce the possibility of overflow, a second adhesive accommodating groove 993 can be placed at the bottom of the second connector 99 (see FIG. 50a and FIG. 51). This means that recesses are created at the bottom of the second connector 99 to hold excess adhesive 92, reducing the likelihood of it overflowing when the second connector 99 is compressed. The shape of the recesses can be one of several, such as straight, cross-shaped, circular, oval, wavy, or in a dot matrix. These recesses also increase the bonding surface between the adhesive 92 and the second connector 99, thereby strengthening the bond between the adhesive 92, the light board 90, and the second connector 99.

This embodiment also provides a light board component 9 assembly method. The light board component 9 produced using this assembly method can greatly reduce the error rate during assembly, lower production costs, and improve production efficiency. This light board component 9 assembly method can be used to assemble the aforementioned light board components 9. For better understanding, an example of this assembly method is provided below. The method includes the following steps:
S101: Referring to FIG. 46 to FIG. 49, providing the supporting member 93, light board 90, and connecting elements 97. The connecting elements 97 include a first connector 98 and a second connector 99. The supporting member 93 has a first surface 931 and a second surface 932 on opposite sides, and the light board 90 has a third surface 901 and a fourth surface 902 on opposite sides. A mounting hole 94 that penetrates both the first surface 931 and the second surface 932 is provided on the supporting member 93.
S102: Referring to FIG. 50a, pre-inserting the first connector 98 through the mounting hole 94 and detachably fixing it to the second connector 99, which is installed on the first surface 931.

In this step, the connecting element 97 corresponding to the mounting hole 94 is detachably fixed to the supporting member 93. The connecting element 97 includes the first connector 98, which is located on one of the two opposite surfaces of the supporting member 93, and the second connector 99 located on the other surface. The first connector 98, the second connector 99, and the supporting member 93 are detachably fixed together based on the mounting hole 94.

Referring to FIG. 50a and FIG. 50b, pre-applying adhesive 92 to the connection areas 903 on the third surface 901 that correspond to the positions of the second connectors 99, or apply the adhesive 92 to the second connectors 99.

In this step, since adhesive 92 is pre-applied to the connection areas 903 on the third surface 901 of the light board 90 corresponding to the positions of the second connectors 99 or directly applied onto the second connectors 99, the light board 90 and the second connectors 99 of the supporting member 93 can be bonded via the adhesive 92. In this step, it is preferred that the thickness of the adhesive 92 is greater than or equal to the first predetermined threshold and less than the second threshold.
S103: Referring to FIG. 50a and FIG. 50b, pressing the third surface 901 of the light board 90 and the first surface 931 of the supporting member 93 together, allowing the second connectors 99 to bond to the light board 90 via the adhesive 92, while the supporting member 93 does not come into contact with the adhesive 92.

In this step, to reduce deformation of the light board 90 and the supporting member 93 during pressing, uniform pressure is applied to the fourth surface 902 of the light board 90 or the second surface 932 of the supporting member 93 during the pressing process.
S104: After the adhesive 92 cures, the light board component 9 is obtained (refer to FIG. 46 to FIG. 49).

Specifically, in this step, after the adhesive 92 has cured, the first connector 98 and the second connector 99 can be separated, allowing the light board 90 to be detached from the supporting member 93, which facilitates maintenance.

It should be understood that the application of this invention is not limited to the examples provided above. For those skilled in the art, modifications or variations can be made based on the above description. All such modifications and variations should fall within the scope of the claims of this application.

What is claimed is:

1. A splicing module, comprising:
at least two middle frames; and
a splicing plate for splicing said at least two middle frames;
wherein said at least two middle frames have a front side for mounting a display module and a rear side opposite to said front side, said middle frame has a rectangular outer contour with a corner region at each of the four vertices of said rectangular, at least one of said corner regions is provided with a splicing plate assembly zone for cooperating with said splicing plate, said splicing plate assembly zone is provided with a splicing screw hole and a positioning pin hole;
wherein said splicing plate includes a plate body and a first threaded fastener, said plate body is provided with a splicing through hole and a positioning pin, said positioning pin is integrally formed with said plate body, said positioning pin is configured to cooperate with said positioning pin hole, said splicing through hole and said splicing screw hole are configured to cooperate with said first threaded fastener to securely connect said splicing plate with said middle frame.

2. The splicing module according to claim 1, wherein said splicing plate assembly zone includes a front assembly zone located on the front side of said middle frame and a rear assembly zone located on the rear side of said middle frame;
wherein said front assembly zone of said middle frame has a recessed area with a depth greater than or equal to the thickness of said splicing plate for embedding a part of said splicing plate, and a corner protrusion is provided in the area of said front assembly zone close to the vertex of said rectangular;
wherein said plate body is provided with a first limiting slot, said first limiting slot features a hollowed-out area, and said corner protrusion cooperates with said first limiting slot.

3. The splicing module according to claim 1, further comprising: a mounting bracket;
a first connecting plate, said first connecting plate having at least two first connecting holes; and
a first external fastener;
wherein the splicing piece includes a connecting hole with an internal thread;
wherein the first external fastener includes an external thread matching the internal thread of the connecting hole of the splicing piece;
wherein said first connecting plate and said splicing plate are located on opposite sides of said mounting bracket, respectively, and are connected and fixed to said mounting bracket through said first external fastener via said first connecting holes and connecting holes.

4. A splicing display screen, comprising:
at least two middle frames spliced together, said middle frame has a rectangular outer contour with a corner region at each of the four corners of said rectangular, at least one of said corner regions is provided with a splicing plate assembly zone for cooperating with said splicing plate, said splicing plate assembly zone is provided with a splicing screw hole and a positioning pin hole;
at least one splicing plate for splicing said at least two middle frames;
at least two display modules, each said display module is mounted on the front side of each said middle frame respectively; and
at least two back covers, each said back cover is mounted on the rear side of each said middle frame, respectively;
wherein said splicing plate includes a plate body and a first threaded fastener, said plate body is provided with a splicing through hole and a positioning pin, said positioning pin is integrally formed with said plate body, said positioning pin is configured to cooperate with said positioning pin hole, said splicing through hole and said splicing screw hole are configured to cooperate with said first threaded fastener to securely connect said splicing plate with said middle frame.

5. The splicing display screen according to claim 4, wherein said positioning pin hole conjoins with the positioning pin of said splicing plate, one end of said first threaded fastener passes through said splicing through hole from the front side of said middle frame and then tightens with said splicing screw hole to achieve secure connection between said middle frame and said splicing plate, or one end of said first threaded fastener passes through said splicing through hole from the rear side of said middle frame and then tightens with said splicing screw hole to achieve secure connection between said middle frame and said splicing plate.

6. The splicing display screen according to claim 4, wherein said splicing plate assembly zone includes a front assembly zone located on the front side of said middle frame and a rear assembly zone located on the rear side of said middle frame; said front assembly zone of said middle frame has a recessed area, the depth of said recess is greater than or equal to the thickness of said splicing plate for accommodating a portion of said splicing plate, said front assembly zone has a corner protrusion in the area near the vertex of said rectangular, said plate body is provided with a first limiting slot, said first limiting slot is a hollowed-out design, and said corner protrusion conjoins with said first limiting slot.

7. The splicing display screen according to claim 4, wherein the conjunction gap between said splicing screw hole and said first threaded fastener is greater than the conjunction gap between said positioning pin hole and said positioning pin.

8. The splicing display screen according to claim 4, further comprising:
a mounting bracket;
a first connecting plate; and
a first external fastener;
wherein said first connecting plate is provided with at least two first connecting holes, said splicing plate is further provided with at least two third connecting holes with internal threads; said splicing plate is installed in the rear assembly zone of said middle frame, and said first connecting holes and said third connecting holes are respectively located on opposite sides of said mounting bracket and are connected through said first external fastener to secure said splicing display screen to said mounting bracket.

9. The splicing display screen according to claim 8, further comprising:
a second connecting plate; and
a second external fastener;
wherein said second connecting plate is provided with a second connecting hole, at least one of said corner regions of said middle frame is provided with an external fixing hole that penetrates said middle frame, and said external fixing hole and said second connecting hole are respectively located on opposite sides of said mounting bracket and are connected through said second external fastener to secure said splicing display screen to said mounting bracket.

10. A splicing display screen, comprising:
a first middle frame and a second middle frame, each of which includes a front side and a rear side opposite to the front side;
at least two display modules, wherein each display module is installed on the front side of the respective middle frame; and
at least two back covers, each installed on the rear side of the respective middle frame;
wherein the adjacent side beams of the first middle frame and the second middle frame are respectively provided with corresponding first electrical through-hole and second electrical through-hole; a first electrical interface component is installed on the back cover of the first middle frame, which includes a fixed part that is connected to the back cover and a movable part that is movably connected to the fixed part; and the movable part can slide in the first direction and is connected to the first electrical interface via a second fastener;
wherein the second middle frame is equipped with a second electrical interface that corresponds to the first electrical interface; said second electrical interface is fixedly connected to the second middle frame and exposed through the second electrical through-hole; and the first electrical interface can slide in the first direction via the movable part to connect to or disconnect from the second electrical interface through the first electrical through-hole.

11. The splicing display screen according to claim 10, further comprising:
an operating component, which includes a rotating shaft, a connecting rod, and a push rod;
wherein the rotating shaft is rotatably connected to the back cover, and the push rod is placed inside a second limiting slot which is on the movable part, and the connecting rod connects the rotating shaft and the push rod.

12. The splicing display screen according to claim 10, wherein at least a portion of the fixed part is positioned inside a guide slot which is configured on the movable part, and the movement of the movable part along the first direction is constrained by the guide slot.

13. The splicing display screen according to claim 10, wherein a positioning component is configured on the movable part; the positioning component includes an elastic protrusion that is connected to the back cover; the positioning component has a first position and a second position along the first direction; the back cover of the first middle frame is provided with a first positioning hole and a second positioning hole; and the positioning component fits with the first positioning hole in the first position and the second positioning hole in the second position.

14. The splicing display screen according to claim 13, wherein the positioning component includes a hollow stud, a spring, and a steel ball positioned inside the hollow stud; and part of the steel ball is pushed out of the end of the hollow stud by the spring, forming the elastic protrusion that can extend into the first positioning hole or the second positioning hole.

15. The splicing display screen according to claim 10, further comprising:
a supporting member, which has opposing first surface and second surface and is provided with a mounting hole that passes through the first surface and the second surface;
a light board, which includes a third surface corresponding to the supporting member; and
a connecting element that connects the light board and the supporting member, wherein the connecting element includes a first connector and a second connector;
wherein the second connector is fixedly connected to the third surface of the light board by an adhesive, and the first connector passes through the mounting hole from the first surface and is detachably connected to the second connector located on the second surface, and neither the supporting member nor the first connector comes into contact with the adhesive.

16. The splicing display screen according to claim 15, wherein the second connector includes an integrally formed screw hole part and a base, and a bottom of the base is fixedly connected with the adhesive.

17. The splicing display screen according to claim 15, wherein the supporting member is provided with a first protrusion facing the light board, and the first protrusion extends outward from the edge of the mounting hole and is not in contact with the adhesive.

18. The splicing display screen according to claim 15, wherein the edge portion and the middle portion of the supporting member are provided with second protrusions facing the light board, the second protrusions are the parts of the supporting member closest to the light board, the distance between the second protrusions and the light board is greater than the distance between the second connector and the light board, and the second protrusions are strip-shaped or column-shaped and extend to the edge and middle portions of the supporting member to provide uniform support and maintain controlled spacing.

19. A middle frame, comprising:
four side beams forming a rectangular outer frame;
wherein the four side beams include a first side beam and a second side beam;
wherein the first side beam is provided with a first fixing hole and a first adjustment hole, and the second side beam is arranged opposite to the first side beam;
wherein the second side beam is provided with a second fixing hole, which corresponds in position to the first fixing hole;
wherein the first adjustment hole is configured to cooperate with a first adjustment component to adjust a gap between the adjacent middle frames; and
wherein the first adjustment component comprises a first bolt, including a bolt head and a stud, and the length of the stud is greater than the depth of the first adjustment hole.

20. The middle frame according to claim 19, further comprising:
a reinforcement elements on at least two of the four side beams, wherein said reinforcement elements are configured to enhance the structural stability of the middle frame;
an alignment grooves on the inner sides of at least two adjacent side beams, wherein said alignment grooves are configured to facilitate precise alignment with adjacent middle frames; and
a fastener guide holes, positioned in proximity to the first and second fixing holes, wherein said fastener guide holes are sized and shaped to ensure accurate placement of fasteners during assembly.
